(19) United States
(12) Patent Application Publication
(10) Pub. No.: US 2025/0117532 A1
(43) Pub. Date: Apr. 10, 2025

(54) USING ARTIFICIAL INTELLIGENCE TO ESTABLISH A MAP BETWEEN OBJECTS IN A COMPUTER MODEL OF A CONSTRUCTION SITE AND A HIERARCHY OF MODELS OF THE CONSTRUCTION SITES

(71) Applicant: DOXEL, INC., Palo Alto, CA (US)

(72) Inventors: John Stalbaum, Palo Alto, CA (US); Richard Will Turner, Palo Alto, CA (US); Arunava Saha, Palo Alto, CA (US); Marin Lukovic, Palo Alto, CA (US); Michael Grinshpon, Palo Alto, CA (US); Rohit Srikonda, Katy, TX (US); Abhishek Singh, Dallas, TX (US)

(21) Appl. No.: 18/911,694

(22) Filed: Oct. 10, 2024

Related U.S. Application Data
(60) Provisional application No. 63/589,083, filed on Oct. 10, 2023.
(60) Provisional application No. 63/589,392, filed on Oct. 11, 2023.
(60) Provisional application No. 63/589,566, filed on Oct. 11, 2023.
(60) Provisional application No. 63/589,264, filed on Oct. 10, 2023.
(60) Provisional application No. 63/589,278, filed on Oct. 10, 2023.
(60) Provisional application No. 63/589,587, filed on Oct. 11, 2023.

(51) Int. Cl. G06F 30/13; G06F 30/27

(52) U.S. Cl. CPC G06F 30/13; G06F 30/27

(57) ABSTRACT

The system obtains a hierarchy representing a construction site, where the hierarchy includes a parent node and a child node, and obtains a first computer model of a first construction site including a first multiplicity of virtual objects. Based on the hierarchy representing the construction site, and the first computer model of the first construction site, the system creates a first map between the hierarchy representing the construction site and the first computer model of the first construction site. The system trains an artificial intelligence based on the first map, and then provides to the artificial intelligence a second computer model of a second construction site. The system receives from the artificial intelligence a second map between the hierarchy representing the construction site and the second computer model.

### CROSS-REFERENCE TO RELATED APPLICATIONS

This application claims the benefit of and priority to the U.S. Provisional Patent Application No. 63/589,083, filed on Oct. 10, 2023, U.S. Provisional Patent Application No. 63/589,392, filed on Oct. 11, 2023, U.S. Provisional Patent Application No. 63/589,566, filed on Oct. 11, 2023, U.S. Provisional Patent Application No. 63/589,264, filed on Oct. 10, 2023, U.S. Provisional Patent Application No. 63/589,278, filed on Oct. 10, 2023, and U.S. Provisional Patent Application No. 63/589,587, filed on Oct. 11, 2023, all of which are hereby incorporated by this reference in their entirety.

### TECHNICAL FIELD

The disclosed teachings generally relate to visual simultaneous localization and mapping (VSLAM).

### BACKGROUND

Constructing complex structures, such as buildings, requires the proper installation or assembly of many components. Construction workers need to properly locate and install or assemble numerous components, such as beams, pipes, ducts, studs, walls, etc. For example, some complex structures have millions of components that need to be installed at a location within an accuracy of an eighth of an inch, or even less in some cases. Unfortunately, the construction process is subject to errors, which can cause significant amounts of re-work and schedule delays. For example, a wall may be installed at a wrong location. If the error is not detected in a timely fashion, a significant amount of re-work may result. For example, a plumber may run water lines through the improperly located wall, an electrician may run electrical wires through the improperly located wall, a carpenter may add sheetrock to the improperly located wall, etc. When the error is detected, the wall may need to be demolished and rebuilt in the proper location in order to rectify the error, and the water lines, electrical wires, and sheetrock may need to be reinstalled. Such errors may cause significant schedule delays and may result in significant additional costs for the construction project. Similar issues exist in the construction of other complex structures, such as airplanes, ships, submarines, space vehicles, etc.

### BRIEF DESCRIPTION OF THE DRAWINGS

Various features and characteristics of the technology will become more apparent to those skilled in the art from a study of the Detailed Description in conjunction with the drawings. Embodiments of the technology are illustrated by way of example and not limitation in the drawings, in which like references may indicate similar elements.

FIG. 1 is a system diagram illustrating an environment in which a

construction monitoring system may be implemented according to some embodiments of the present disclosure.

FIG. 2 is an example of a visualization of three-dimensional (3D) point

cloud data obtained by a light detection and ranging (LIDAR) system of a three-dimensional structure undergoing construction.

FIGS. 3A through 3C are illustrations that depict alignment of data derived from a model of a building, such as the reference structure, and sensor data derived from a sensor reading of a building, such as a building under construction.

FIG. 4 is a flowchart that illustrates a method for human-assisted constraint annotation for VSLAM.

FIG. 5 is a flowchart that illustrates a method for unsupervised lifecycle management for VSLAM-based construction monitoring.

FIG. 6 is a flowchart that illustrates a method for automatically detecting predictable relationships between installed objects at construction sites for the purpose of augmenting predictions based on sensor data.

FIG. 7 is a flowchart that illustrates a method for adding metadata to low-quality building information modeling (BIM) data.

FIG. 8 is a flowchart that illustrates a method for instance segmentation via BIM.

FIG. 9 is a flowchart that illustrates a method for contrastive-like loss for time series.

FIG. 10 shows a recording of a construction site.

FIG. 11 shows a mapping between a recording of objects at a construction site and virtual objects in a three-dimensional computer model.

FIG. 12 is a flowchart of a method to establish a correspondence between a construction site and a three-dimensional computer model of the construction site.

FIG. 13 is a flowchart of a method to determine correspondence between two videos of a construction site, taken at two different times, where the correspondence can be used for construction site monitoring.

FIG. 14 shows a hierarchy of objects present at a construction site.

FIG. 15 is a flowchart of a method to use an artificial intelligence (AI) to establish a map between objects in a computer model of a construction site and a hierarchy of models of the construction site.

FIG. 16 is a flowchart of a method to train and use an artificial intelligence to determine progress of construction at a construction site.

FIG. 17 is a block diagram illustrating an example of a processing system in which at least some operations described herein can be implemented.

The drawings depict various embodiments for the purpose of illustration only. Those skilled in the art will recognize that alternative embodiments may be employed without departing from the principles of the technology. Accordingly, while specific embodiments are shown in the drawings, the technology is amenable to various modifications.

### DETAILED DESCRIPTION

In one embodiment, the disclosed system obtains a floor plan associated with a construction site, and a three-dimensional computer model associated with the construction site, where the floor plan represents a two-dimensional projection of the three-dimensional computer model associated with the construction site. Both the floor plan and the three-dimensional computer model can be part of BIM. The system obtains a trajectory through the construction site, and a video of the construction site, where the trajectory indicates a path of a camera recording the video of the construction site, and where the video includes a sequence of images including an initial image indicating a beginning of the video and an image A following the initial image.

The system establishes a correspondence between the trajectory and the floor plan, where the correspondence indicates how a location on the trajectory corresponds to a location on the floor plan, and where the correspondence indicates an initial location associated with the trajectory that corresponds to the initial image. Based on the correspondence between the trajectory and the floor plan, the initial image, and the initial location, the system creates a virtual camera associated with the three-dimensional computer model and a virtual trajectory, where the virtual trajectory influences multiple virtual objects visible to the virtual camera, and where the multiple virtual objects visible to the virtual camera match multiple objects visible in the initial image. The virtual camera can be a 360° camera, or a non-360° camera.

Based on the initial image and the image A, the system determines a transformation of the camera recording the video of the construction site between the initial image and the image A. The system applies the transformation of the camera to the virtual camera to obtain a virtual trajectory of the virtual camera associated with the three-dimensional computer model, where the virtual trajectory of the virtual camera corresponds to the trajectory of the camera.

In the second embodiment, the system obtains a video A recorded at a construction site captured at a time A, and a virtual trajectory A associated with a virtual camera A, where the video A includes a sequence of images A including an initial image A indicating a beginning of the video A and an image A following the initial image A, where the virtual trajectory A indicates a path of the virtual camera A through a three-dimensional computer model of the construction site, and where a video recorded by the virtual camera A moving along the virtual trajectory A matches the video A recorded at the construction site. The system obtains a video B of the construction site captured at a time B different from the time A, where the video B includes a sequence of images B including an initial image B indicating a beginning of the video B and an image B following the initial image B, and where the sequence of images B is different from the sequence of images A. The image A and/or B can be a panorama. The sequence of images B follows a different trajectory than the sequence of images A.

The system creates a tree data structure A representing the sequence of images, where the tree data structure can be a spatial tree data structure. The system creates a tree data structure B representing the sequence of images B. The system establishes a correspondence between the tree data structure A and the tree data structure B by creating a map between the image B associated with the sequence of images B and the image A in the sequence of images A by searching the tree data structure A for the image A in the sequence of images A similar to the image B more efficiently than searching by comparing the image B to each image in the sequence of images A. The system obtains a location A of the virtual camera A corresponding to the image A. Based on the map between the image B and the image A, the system determines a location B of a virtual camera B corresponding to the image B, where the location B of the virtual camera B indicates multiple objects in the three-dimensional computer model of the construction site, and where the multiple objects are visible to the virtual camera B.

In a third embodiment, the system obtains a hierarchy representing a construction site, where the hierarchy includes a parent node and a child node, and where the parent node indicates a function associated with an object at the construction site and the child node indicates an object type associated with the object at the construction site. The system obtains a three-dimensional computer model A of a construction site A including a multiplicity of virtual objects A, where a virtual object A among the multiplicity of virtual objects A corresponds to a first object at the construction site A.

Based on the hierarchy representing the construction site, and the three-dimensional computer model of the construction site, the system creates a map A between the hierarchy representing the construction site and the three-dimensional computer model A of the construction site. The system trains an artificial intelligence based on the map A and provides to the artificial intelligence a three-dimensional computer model B of a construction site B, where the three-dimensional computer model B is different from the three-dimensional computer model A. The system receives from the artificial intelligence a map B between the hierarchy representing the construction site and the three-dimensional computer model B.

In a fourth embodiment, the system obtains a hierarchy representing a construction site, where the hierarchy includes a parent node and a child node, and where the parent node indicates a function associated with an object at the construction site and the child node indicates an object type associated with the object at the construction site. The system obtains multiple questions associated with a node in the hierarchy representing the construction site A, where a question among the multiple questions requests an indication of a stage of construction associated with an object A at the construction site A represented by the node, and where the question among the multiple questions requests an answer from a binary set.

The system obtains a video of an object A recorded at the construction site A, and presents the video of the object A and the multiple questions to a user. The system receives the answer associated with the binary set from the user, and creates an artificial intelligence training dataset based on the answer associated with the binary set and the recording of the object A at the construction site A.

The embodiments set forth below represent the necessary information to enable those skilled in the art to practice the embodiments and illustrate the best mode of practicing the embodiments. Upon reading the following description in light of the accompanying figures, those skilled in the art will understand the concepts of the disclosure and will recognize applications of these concepts that are not particularly addressed herein. These concepts and applications fall within the scope of the disclosure and the accompanying claims.

The disclosed technology can be embodied using special-purpose hardware (e.g., circuitry), programmable circuitry appropriately programmed with software and/or firmware, or a combination of special-purpose hardware and programmable circuitry. Accordingly, embodiments may include a machine-readable medium having instructions that may be used to program a computing device to examine video content generated by an electronic device, identify elements included in the video content, apply a classification model to determine an appropriate action, and perform the appropriate action.

The purpose of terminology used herein is only for describing embodiments and is not intended to limit the scope of the disclosure. Where context permits, words using the singular or plural form may also include the plural or singular form, respectively.

As used herein, unless specifically stated otherwise, terms such as “processing,” “computing,” “calculating,” “determining,” “displaying,” “generating,” or the like, refer to actions and processes of a computer or similar electronic computing device that manipulates and transforms data represented as physical (electronic) quantities within the computer's memory or registers into other data similarly represented as physical quantities within the computer's memory, registers, or other such storage medium, transmission, or display devices.

As used herein, terms such as “connected,” “coupled,” or the like, may refer to any connection or coupling, either direct or indirect, between two or more elements. The coupling or connection between the elements can be physical, logical, or a combination thereof.

References to “an embodiment” or “one embodiment” mean that the particular feature, function, structure, or characteristic being described is included in at least one embodiment. Occurrences of such phrases do not necessarily refer to the same embodiment, nor are they necessarily referring to alternative embodiments that are mutually exclusive of one another.

Unless the context clearly requires otherwise, the words “comprise” and “comprising” are to be construed in an inclusive sense rather than an exclusive or exhaustive sense (i.e., in the sense of “including but not limited to”).

As used herein, the term “based on” is also to be construed in an inclusive sense rather than an exclusive or exhaustive sense. Thus, unless otherwise noted, the term “based on” is intended to mean “based at least in part on.”

As used herein, the term “module” may refer to software components, hardware components, and/or firmware components. Modules are typically functional components that can generate useful data or other output(s) based on specified input(s). A module may be self-contained. A computer program may include one or more modules. Thus, a computer program may include multiple modules responsible for completing different tasks or a single module responsible for completing multiple tasks.

When used in reference to a list of multiple items, the word “or” is intended to cover all of the following interpretations: any of the items in the list, all of the items in the list, and any combination of items in the list.

The sequences of steps performed in any of the processes described herein are exemplary. However, unless contrary to physical possibility, the steps may be performed in various sequences and combinations. For example, steps could be added to, or removed from, the processes described herein. Similarly, steps could be replaced or reordered. Thus, descriptions of any processes are intended to be open-ended.

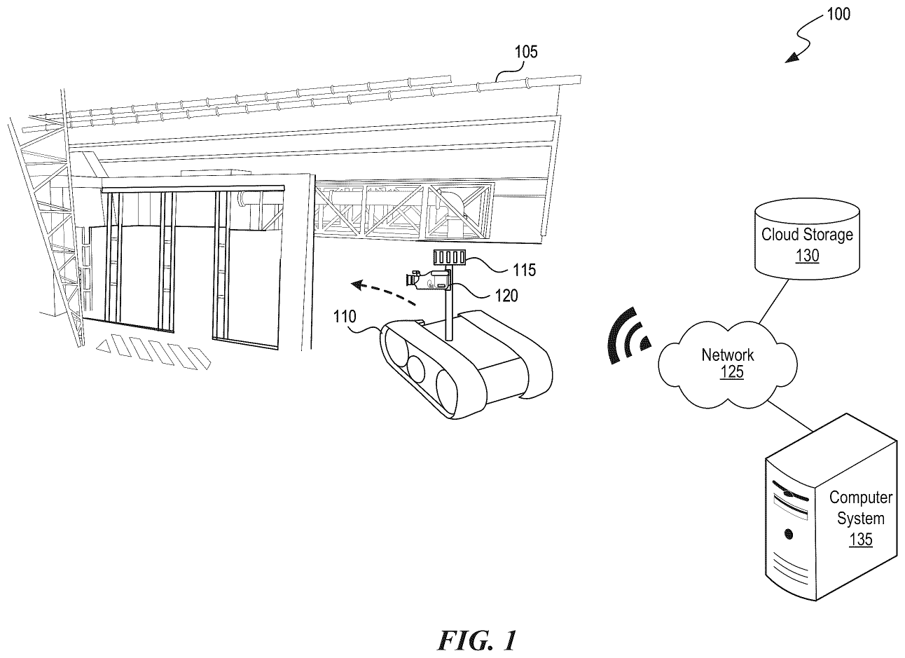

FIG. 1 is a system diagram illustrating an environment in which a construction monitoring system may be implemented according to some embodiments of the present disclosure. In environment 100 of FIG. 1, robot 110 is traversing a construction site. Robot 110 navigates around building 105 and other portions of the construction site in order to obtain sensor readings related to physical properties associated with the construction project. For example, robot 110 obtains sensor readings of some or all of building 105. While a robot is used in this example, any of various methods can be utilized to obtain sensor readings related to the construction project. For example, a drone that includes a sensor can be utilized to autonomously navigate around the construction site and take sensor readings. In another example, a person with a backpack that contains a sensor can walk around the construction site and take sensor readings.

In the example of FIG. 1, robot 110 traverses a path that is optimized to efficiently obtain sensor readings of all accessible portions of building 105. In some embodiments, robot 110 also traverses and obtains sensor readings of areas outside of building 105. For example, robot 110 may obtain sensor readings of a landscape (to monitor development progress of landscaping), a sports facility (to monitor construction progress of, e.g., a basketball court, tennis court, pool, etc.), another building (to monitor construction progress of the other building), a parking lot or parking structure (to monitor construction progress of the parking lot or structure), etc.

As part of the construction project, a project design team, with team members such as architects, structural engineers, mechanical engineers, electrical engineers, etc., developed plans for the construction project, including design plans for the various components associated with building 105. The components can include, for example, structural beams, floors, flooring, walls, plumbing, electrical wiring, fire sprinklers, door frames and doors, external windows, internal windows, bathrooms, computer centers, surgery centers, lighting, landscaping, air conditioners, ducts, water heaters, water filtration systems, gyms, cafeterias, cabinets, closets, security systems, bulk heads, watertight doors, engines, propellers, etc. The design team sets the design of the construction project via one or more computer-aided design (CAD) applications.

Some CAD applications may inherently support three-dimensional design capture and visualization, while others may not. Where three-dimensional analysis is required and a CAD application does not inherently support three-dimensional views, the CAD application can store data needed to generate a three-dimensional view, such as elevation, depth, etc. of various components, which can be utilized to determine three-dimensional locations of the components. Data derived from the design plan data, which can be or include the design plan data, can be stored at cloud storage 130, can be stored at storage local to the robot 110, or can be stored at other locations.

Robot 110 has access to design plan data and is able to utilize the design plan data to generate a three-dimensional representation of building 105, and is able to navigate around building 105 by use of the three-dimensional representation. For example, a computer, which can be physically coupled to robot 110 or can be remote, can correlate features of building 105, as determined based on sensor readings of building 105, with features of the design plans of building 105, and can use the design plans to navigate around building 105, taking into account that the construction of building 105 is only partially complete. In some embodiments, robot 110 is able to navigate around building 105 without having access to a three-dimensional representation of building 105. For example, the boundaries of building 105 can be input to robot 110, the coordinates of a geo-fence can be transmitted to robot 110, etc., and robot 110 can use a navigation system, such as the Global Positioning System (GPS) or autonomous navigation capabilities, to traverse the area around building 105 or any other area related to the construction project.

As robot 110 traverses the construction site, robot 110 uses its sensors, such as LIDAR system 115 and imaging system 120, to obtain sensor readings. The sensor readings of LIDAR system 115 include three-dimensional point cloud data, also referred to as three-dimensional point data of a points cloud, from which physical properties of components related to the construction project can be derived. A portion of the three-dimensional point cloud data includes data from which physical properties of components related to building 105, such as three-dimensional locations of various surface points of various components of or associated with building 105, can be derived.

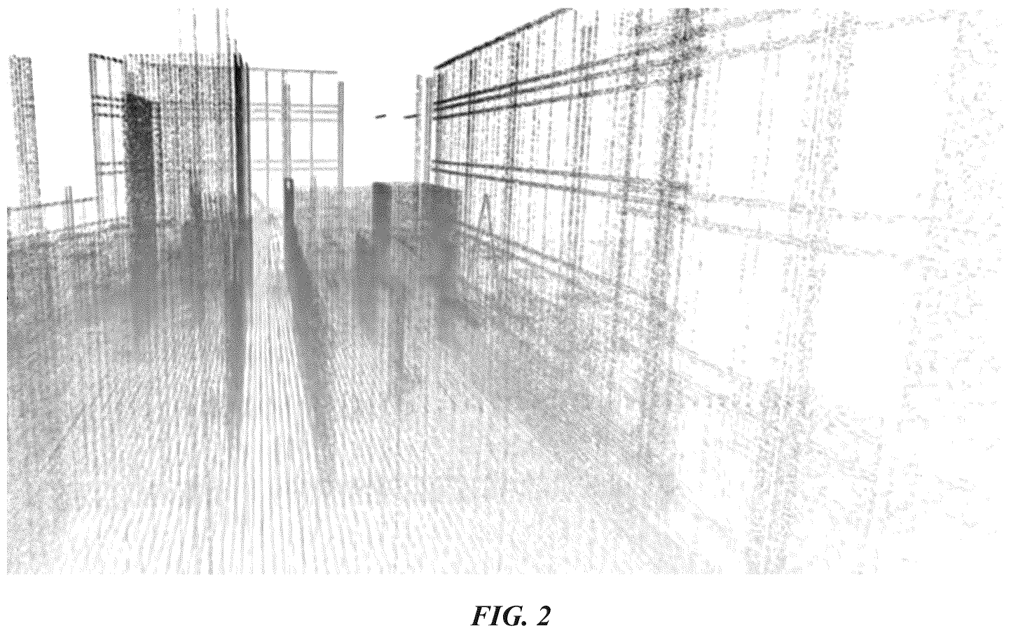

FIG. 2 is an example of a visualization of three-dimensional point cloud data obtained by a LIDAR system of a three-dimensional structure undergoing construction. The sensor readings of imaging system 120 include imaging data, such as still picture or video data, from which physical properties of components related to the construction project can be derived. A portion of the imaging data includes data from which physical properties of components related to building 105 can be derived, such as the color or texture of surfaces of components, among others.

Examples of components of building 105 include a pipe, beam, wall, floor, ceiling, toilet, roof, door, door frame, metal stud, wood stud, light fixture, piece of sheetrock, water heater, air conditioning unit, water fountain, cabinet, table, desk, refrigerator, and sink, among others. Examples of components of landscaping include a tree, shrub, bench, mound, walkway, light fixture, sprinkler head, and drainage fixtures, among others. Examples of physical properties of components include three-dimensional locations of points on the surface of the component, the surface texture of the component, the three-dimensional location of the component, the color of the component, the density or weight of the component, the reflectivity of the component, material type, unique identification of a component, unique identification of a material of a component, a flow rate, and a gauge or thickness of a material of the component, among others.

In this example, robot 110 wirelessly transmits data derived from the sensor readings, which can be or include the raw sensor readings, to cloud storage 130 via network 125 for storage, where computer system 135 is able to access the stored data. Network 125 can be or can include the Internet. In some embodiments, robot 110 stores the data derived from the sensor data at storage local to robot 110, where computer system 135 is able to access the data. In some embodiments, computer system 135 is local to robot 110.

Computer system 135 accesses the data stored at cloud storage 130 or at local storage. Computer system 135 creates a three-dimensional design view based on the design plan data and identifies the various components of the three-dimensional design view. Computer system 135 creates a three-dimensional progress view based on the sensor data and identifies the various components of the three-dimensional progress view. Computer system 135 maps components of the three-dimensional progress view to corresponding components of the three-dimensional design view and analyzes the data to detect physical discrepancies between the two views. In some embodiments, when a deviation exists relative to a predetermined threshold, the discrepancy is reported as an error.

Physical discrepancies or deviations from an expected physical structure can include, for example, a three-dimensional progress view component being located at a different location as compared to its corresponding three-dimensional design view component, being of a different dimension as compared to its corresponding three-dimensional design view component, being of a different color as compared to its corresponding three-dimensional design view component, being composed of a different material as compared to its corresponding three-dimensional design view component, having a different surface texture as compared to its corresponding three-dimensional design view component, being a different component as compared to its corresponding three-dimensional design view component (e.g., being a 45° angle joint as compared to a 90° angle joint, being a brand 1 air conditioning unit as compared to a brand 2 air conditioning unit, or being an iron pipe as compared to a copper pipe).

In some embodiments, the difference may need to be greater than a predetermined threshold to be deemed as a reportable discrepancy (e.g., a location error in excess of ⅛ of an inch). In some cases, the threshold, also sometimes referred to as accuracy tolerance, is input by the design team or by other methods as annotations on the components of the design plans. For example, a pipe may have an accuracy tolerance of ⅛ of an inch, and that tolerance may be added as an annotation on the pipe via a CAD application used to create design plan data. When the discrepancy between the location of the component in the three-dimensional design view and the three-dimensional progress view is greater than the accuracy tolerance, the discrepancy can be reported as an error.

Computer system 135 can detect other types of deviations. In some embodiments, the data stored at cloud storage 130 includes schedule data or other performance metrics. Computer system 135, based on the above mapping and analysis, is able to determine which components have been properly installed, which have not been installed at all or have been only partially installed, or which have been installed incorrectly. Based on this analysis, computer system 135 can detect various other types of discrepancies. For example, computer system 135 can detect a discrepancy between progress projected by a schedule or expected progress and actual progress (e.g., progress as determined based on an analysis of components of the three-dimensional progress view, giving credit for those components that have been properly installed, and not giving credit for components that have discrepancies that need to be addressed).

As another example, computer system 135 can detect a discrepancy between a planned or targeted productivity level and an actual productivity level. In some embodiments, alerts can be displayed for different types of discrepancies. For example, an application running on a mobile device can enable a user to set alert notification parameters, including setting an alert for a planned or targeted productivity level/score, or setting an alert for a planned progress milestone. Based on the above analysis, mapping, and discrepancy detection, computer system 135 can provide construction progress status. For example, a mobile application or web interface can provide a milestone progress status for several groups of tasks of a building construction project.

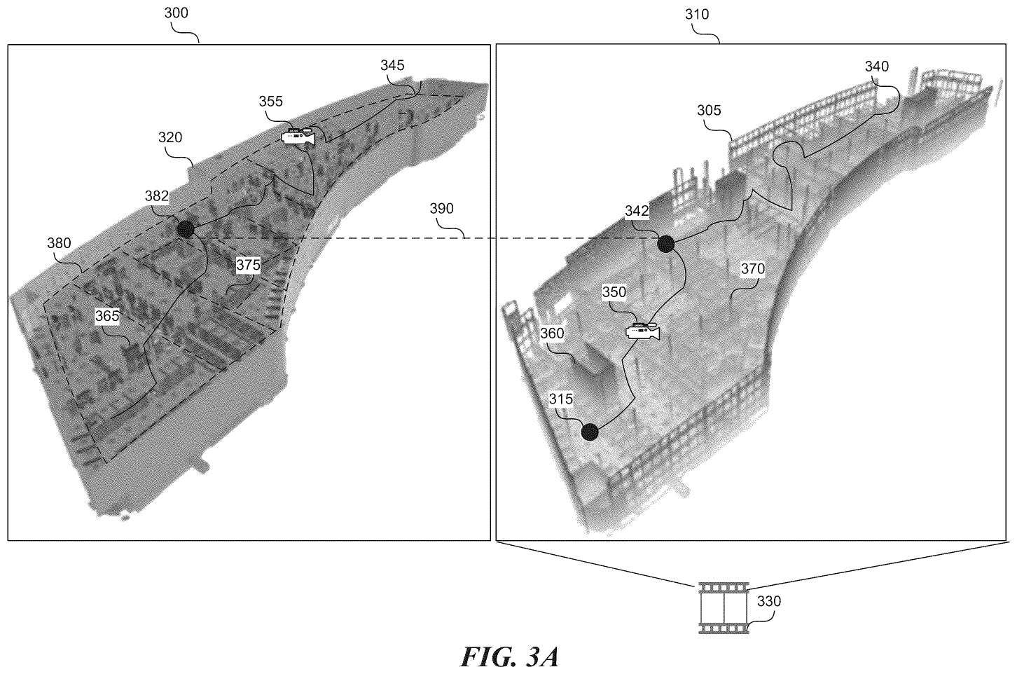

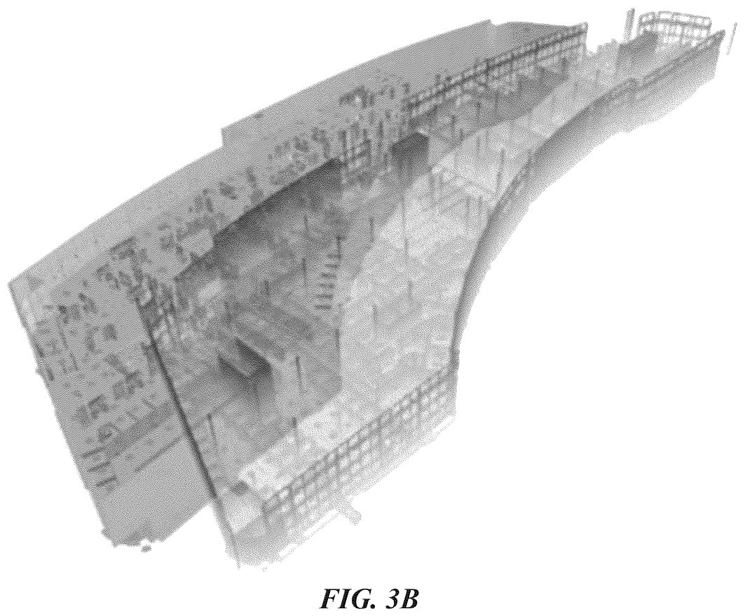

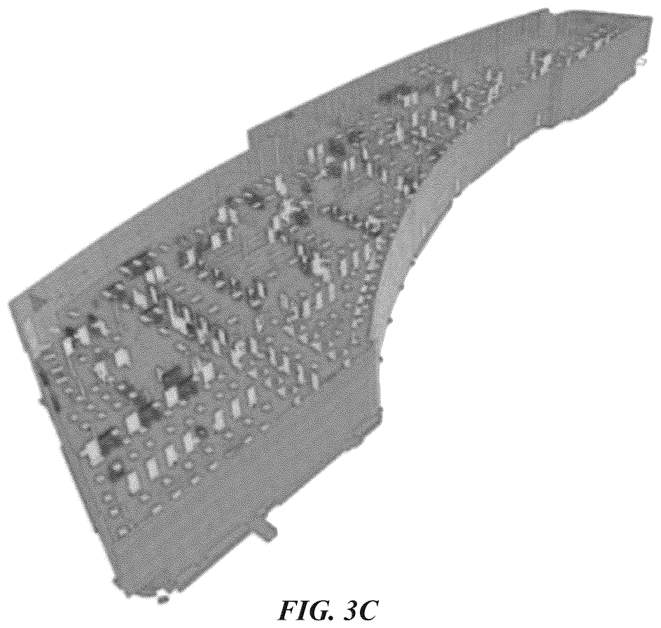

FIGS. 3A through 3C are illustrations that depict alignment of data derived from a model of a building, such as the reference structure, and sensor data derived from a sensor reading of a building, such as a building under construction. Specifically, FIG. 3A depicts two indications, e.g., views, a view 300 of a reference structure and a view 310 of a structure under construction, e.g., construction site 305. FIG. 3B depicts the two views 300, 310 as they conceptually begin to align, and FIG. 3C shows the two views 300, 310 after alignment. FIGS. 3A through 3C are conceptualizations of the alignment process and may not reflect how a computer system actually aligns the views. For example, the computer system may not incrementally move the two views closer together.

The view 300 of the reference structure can be a view of a three-dimensional computer model 320 representing the completed stage of the construction site 305. The three-dimensional computer model 320 can be included in the BIM, as described in this application. The view 310 can be a recording 330 of the physical construction site 305. The recording 330 can be a point cloud, an image, or a panorama of the physical construction site 305. The recording 330 can be a temporal sequence of representations, e.g., images, such as a video.

The view 310 can also include a trajectory 340 of a physical camera 350 through the construction site 305. The physical camera 350 can record multiple objects 360, 370 visible to the physical camera 350 in the recording 330 of the construction site 305.

The system, as described in this application, can create a virtual camera 355 associated with the three-dimensional computer model 320, and a virtual trajectory 345 of the virtual camera 355, where the virtual trajectory 345 corresponds to the physical trajectory 340, and influences the multiple virtual objects 365, 375 visible to the virtual camera. The virtual objects 365, 375 match objects 360, 370 visible to the physical camera 350.

For example, to create the virtual camera 355, the system can establish a correspondence 390 between the trajectory 340 and a floor plan 380 representing a two-dimensional projection of the three-dimensional computer model 320 associated with the construction site. The correspondence 390 can indicate how a location 342 on the trajectory 340 corresponds to a location 382 on the floor plan, and can indicate an initial location 315 associated with the trajectory 340 that corresponds to an initial image.

Based on the correspondence 390 between the trajectory 340 and the floor plan 380, the initial image, and the initial location 315, the system can create a virtual camera 355 associated with the three-dimensional computer model 320 and a virtual trajectory 345.

FIGS. 3A through 3C reflect a common practice in the construction industry to compare the scan image of a three-dimensional structure undergoing construction to a computer model (e.g., CAD model) that depicts the expected three-dimensional structure. This is performed periodically with respective instances of scan images of the three-dimensional structure that can be compared to instances of a computer model that track the progression of the ongoing construction of the three-dimensional structure.

This allows an analyst to check that the ongoing construction of the three-dimensional structure is closely following the instances of the computer model of the three-dimensional structure undergoing construction, where every element of the three-dimensional structure is represented as a geometrical shape with known three-dimensional coordinates. As previously described, the construction industry is widely adopting a technique that involves using laser scanners and other means to scan a three-dimensional structure that is undergoing construction. A result of the three-dimensional scan is a dataset representing points in three-dimensional space referred to as three-dimensional point cloud data that forms a “points cloud.”

To compare the progress of the ongoing actual construction to an expected construction of a structure, an analyst is tasked with aligning three-dimensional point cloud data of the structure with a computer model that depicts the expected three-dimensional structure undergoing construction. Specifically, a coordinate frame of a scan image of a three-dimensional structure undergoing construction must be aligned with a coordinate frame of a computer model that depicts the expected three-dimensional structure at the point in time when the three-dimensional structure is undergoing construction.

An alignment procedure typically involves positioning crosshair reference marks at different locations of ongoing construction of a structure. Accordingly, a scan image of the three-dimensional structure includes embedded images of the crosshair reference marks. An analyst must then manually locate the crosshair marks in the three-dimensional point cloud data derived from the scan image. The analyst selects each crosshair individually and establishes a correspondence with a crosshair mark in the computer model of the expected three-dimensional structure. In other words, the analyst must manually map the crosshair marks obtained from the scan image of the ongoing construction to corresponding crosshair marks in the computer model. Therefore, the alignment process is laborious, time-consuming, and a costly process that results in delays (e.g., days, weeks) before data about a scan image is even ready to compare against an expected representation in the computer model.

To track the progress of ongoing construction until it is brought to completion, the process of aligning three-dimensional point cloud data and an instance of a computer model must be repeated periodically. For example, a scan image can be obtained periodically and compared to a corresponding computer model of the same coordinate frame at an expected point in time of the ongoing construction.

Accordingly, the process of mapping three-dimensional point cloud data to an instance of a computer model is periodic at successive points in time. Consequently, the benefits of ensuring that ongoing construction of a three-dimensional structure does not deviate from its expected three-dimensional model are vastly outweighed by construction delays and costs that result from periodically repeating the laborious, time-consuming, and costly alignment process before even analyzing the differences between the actual and expected representations. That is, any savings that result from avoiding the need to re-work construction are negated by the costs that result from delays in construction to prepare and perform the deviation analysis. Consequently, the manual mapping process is cost-prohibitive and unsuitable for repetitive low-latency data capture for deviation analysis.

### Simultaneous Localization and Mapping Techniques Used in Determining the Stage of Construction

Generally, simultaneous localization and mapping (SLAM) is a technology whereby sensors are used to map a device's surrounding area while simultaneously locating the device itself within that area. Sonar and laser imaging are a couple of examples of how this technology comes into play. But unlike a technology such as LIDAR that uses an array of lasers to map an area, visual SLAM (VSLAM) uses a single camera for collecting data points and creating a map. The single vision sensor can be a monocular, stereo vision, omnidirectional, or Red Green Blue Depth (RGBD) camera. There is no single algorithm to perform VSLAM; in addition, this technology uses three-dimensional vision for location mapping when both the location of the sensor and its broader surroundings are unknown.

VSLAM systems can, without the involvement of any other sensors, construct an internally consistent geometric model of the world, including information about the camera, poses of the input dataset, and locations of real-world objects in these cameras' shared coordinate space. However, the results of such systems suffer from several flaws. For example, since this variant of SLAM does not use any other sensors such as a GPS receiver, an inertial measurement unit (IMU) sensor, or a depth sensor, there is no readily available way to scale the reconstruction, e.g., point cloud, to the real world, or geo-register it. Even if it is practical and cost-effective to add additional sensors, the addition of such sensors lowers the appeal of the technique. For example, GPS receivers do not work well indoors and IMU units are not able to precisely determine the needed scale, in practical situations. And affordable depth sensors often do not work outdoors and/or have the range needed to deal with large areas. Also, without frequent loop closure and expensive correspondence search, the solution is imperfect due to drift that has accumulated from pose and landmark estimations in one region being used to estimate pose and landmark estimations in another region, without any direct connection between topologically distant regions. The disclosed technology overcomes the aforementioned drawbacks.

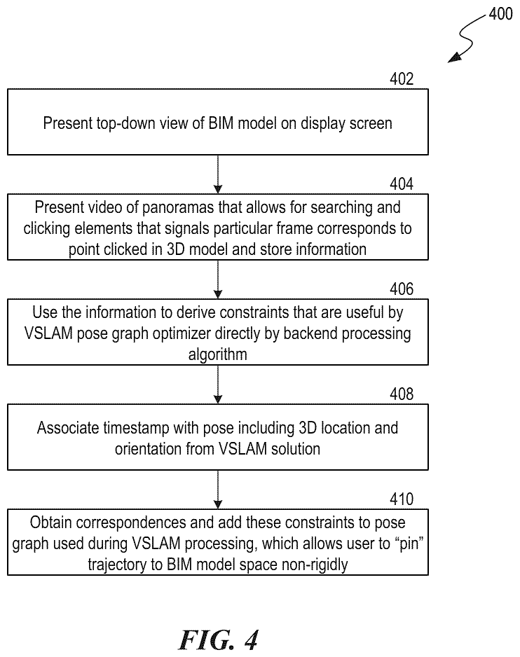

FIG. 4 is a flowchart that illustrates a method 400 for human-assisted constraint annotation for VSLAM. The method 400 can be performed by a computing system. At 402, a top-down view of a BIM is presented on a display screen. BIM is a process supported by various tools, technologies, and contracts involving the generation and management of digital representations of physical and functional characteristics of places. BIMs are computer files (often but not always in proprietary formats and containing proprietary data) which can be extracted, exchanged, or networked to support decision-making regarding a built asset. BIM software is used by individuals, businesses, and government agencies who plan, design, construct, operate, and maintain buildings and diverse physical infrastructures, such as water, refuse, electricity, gas, communication utilities, roads, railways, bridges, ports, and tunnels. The top-down view allows a user to select points in the three-dimensional model included in the BIM file and obtain (x, y) coordinates.

At 404, a video of panoramas is presented, which allow a user to search through the video and click a user interface (UI) element that signals that a particular frame corresponds to the point clicked in the three-dimensional model included in the BIM file. The UI stores the following information: (x₀, y₀)<->timestamp_1.

At 406, the stored information is used to derive constraints that are used by a VSLAM pose graph optimizer.

The pose graph is initially generated from BIM models, the panoramas, and the correspondence between the panoramas and the BIM three-dimensional model. A pose graph is a graphical representation of the poses and their relationships. In this graph, the nodes represent the poses (e.g., the positions and orientations of a robot or a camera at different time steps), and the edges represent the spatial constraints or measurements between the poses.

The system uses the pose graph in pose graph optimization to minimize the errors in the estimated poses by considering the relationships and constraints between them. In pose graph optimization, the system aims to find the best set of poses that satisfy these constraints as closely as possible. The system achieves this by minimizing a global error function, which measures the difference between the observed constraints and the predicted constraints based on the current pose estimates. The global error function the system uses is the difference between the panoramas and the BIM three-dimensional model. The optimization process adjusts the poses to reduce this error, resulting in a more accurate and consistent set of poses.

At 408, a timestamp is associated with a pose consisting of a three-dimensional location and orientation from a VSLAM solution, of the form (x, y, z, r), where r is some rotation representation. If it is assumed that the z-level on the left-hand side and the right-hand side of the correspondence above is identical, one can obtain:

$$( {x}_{0} , {y}_{0} , {z}_{0} ) ↔ ( {x}_{1} , {y}_{1} , {z}_{1} , {r}_{1} ) .$$

If it is further assumed that the camera orientation estimate is correct, the following is obtained:

$$( {x}_{0} , {y}_{0} , {z}_{0} , {r}_{0} ) ↔ ( {x}_{1} , {y}_{1} , {z}_{1} , {r}_{1} ) .$$

At 410, the system obtains several of these correspondences and adds these constraints to the pose graph used during VSLAM processing, which allows the user to “pin” the trajectory to the BIM model space nonrigidly. This result has the following effects:
a. geo-registers the panoramas to model space,
b. corrects the scale of the poses and geometry of the reconstruction, and
c. nonrigidly corrects the overall shape of the reconstruction, reducing drift.

This solves the drift problem as mentioned earlier, without introducing additional unreliable and expensive sensors.

Geo-registering and scaling a set of panoramas can be used to effectively perform a variety of value-generating activities such as tracking installation quality and quantity. By using this method, it is possible to forgo the use of expensive LIDAR sensors that are currently in common use to perform the same activity, resulting in cost savings and opening up the use of three-dimensional construction as a tracking mechanism to a much wider range of business use cases, such as smaller and cheaper construction projects with tighter profit margins.

Previously, ORB-SLAM 3 could be used to reconstruct sequences of camera data to obtain an arbitrarily scaled and unaligned reconstruction, and is probably the closest predecessor. However, the technique does not allow for geo-registration and real-world scaling.

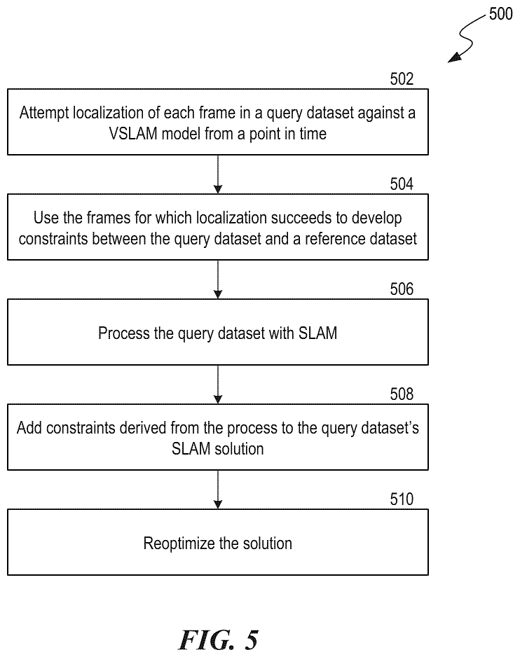

FIG. 5 is a flowchart that illustrates a method 500 for unsupervised lifecycle management for VSLAM-based construction monitoring. Localization in the context of SLAM can associate data in two separate SLAM reconstructions, using visual pattern recognition techniques. Feature detection, extraction, and matching algorithms such as SIFT, SURF, or ORB are used to obtain visual associations. RANSAC and some version of the PnP problem are used to obtain a transformation between individual frames of the query dataset and the global coordinate frame of the reference dataset. In a SLAM context, the resulting frame poses are often used to perform autonomous navigation through an environment.

The disclosed technology includes a system in which the data from a localization process is used to minimize the need for human intervention in construction monitoring.

Construction monitoring has a variety of commercial purposes that generate tremendous value. Using a variety of sensors, it is possible to obtain localized panoramas of a construction site frequently, over its lifecycle. This data can be rapidly turned around to provide valuable insights to owners and contractors, removing the need for re-work and allowing accurate prediction of cost and completion.

Given an initial VSLAM solution, including data structures necessary to perform localization, in an environment, that is further registered to the coordinate space of a BIM model, the system can robustly register subsequent datasets without any human input. The system leverages vision-based pattern recognition to ensure robust continuous operation in rapidly changing environments, while relying on model-based registration refinement to remove drift.

At 502, the method begins by attempting localization of each frame in the query dataset against a VSLAM model from a prior point in time.

At 504, the frames for which localization succeeds are used to develop constraints between the query dataset and the reference dataset. Optionally, those constraints are refined using Iterative Closest Point (ICP) from the points in the three-dimensional reconstruction of the query dataset and the construction model.

At 506, the query dataset is then processed with SLAM.

At 508, the constraints derived from the process are added to the query dataset's SLAM solution.

At 510, the solution is reoptimized.

The result of the method 500 has the following advantages over an uninformed SLAM solution obtained without constraints to the reference dataset:
If the reference dataset was geo-registered, the query dataset is now geo-registered as well.
If the reference dataset was extremely accurate, the accuracy of the query dataset is also improved.

Once the method 500 is complete, the result of this method 500 bootstraps the processing of the next query dataset.

Being able to perform robust registration of two-dimensional imagery to a construction site allows the annotation, through machine learning (ML) or manual methods, of various components. This annotation unlocks profound customer insights that are presently generating significant revenue and business value.

Mobile toolkits such as Apple's ARKit and Google's ARCore provide methods of localization. However, these toolkits do not provide methods to register to construction models.

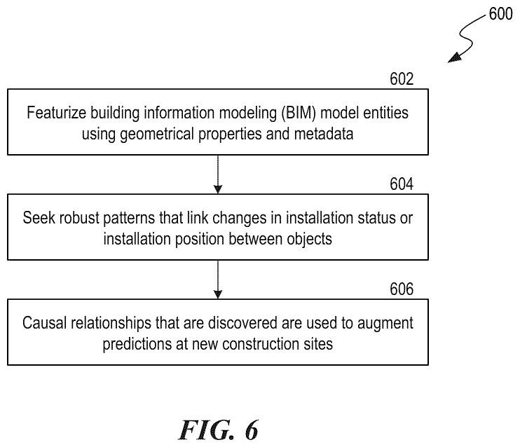

FIG. 6 is a flowchart that illustrates a method 600 for automatically detecting predictable relationships between installed objects at construction sites for the purpose of augmenting predictions based on sensor data. The disclosed technology goes a step beyond the existing connectivity graph/dependency graph (CG/DG) methods. With CG/DG, humans annotate causal relationships using common sense or domain-specific knowledge, and then develop heuristics or train models to predict these human annotations. The disclosed technology directly discovers causal relationships from the dataset using existing pattern recognition methods, which significantly automates model development processes and perhaps uncovering unexpected but robust relationships between components.

The disclosed technology includes causal discovery algorithms that operate on a large dataset to detect causal relationships between (i) installation date and (ii) installation quality of objects installed at a construction site. The method can be performed by a computer system.

At 602, the system creates or defines features based on BIM entities by using geometrical properties and metadata. BIM is a process supported by various tools, technologies, and contracts involving the generation and management of digital representations of physical and functional characteristics of places. BIMs are computer files (often but not always in proprietary formats and containing proprietary data) which can be extracted, exchanged, or networked to support decision-making regarding a built asset. BIM software is used by individuals, businesses, and government agencies who plan, design, construct, operate, and maintain buildings and diverse physical infrastructures, such as water, refuse, electricity, gas, communication utilities, roads, railways, bridges, ports, and tunnels.

At 604, automated methods are used to seek robust patterns that link changes in installation status or installation position between objects.

At 606, the causal relationships that are discovered are used to augment predictions at new construction sites.

This disclosed technology is advantageous to any entity that gathers a similar dataset on schedule delays and where incorrect installations on construction sites creates a need for methods for extracting predictable patterns from that data.

### Using Artificial Intelligence to Determine Stage of Construction

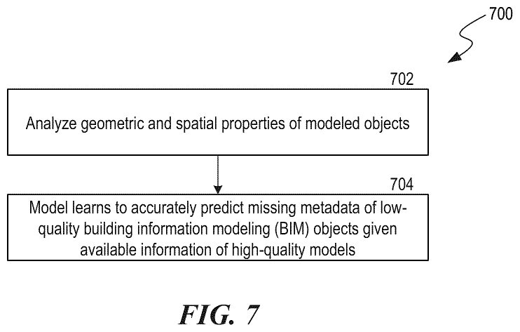

FIG. 7 is a flowchart that illustrates a method 700 for adding metadata to low-quality BIM data.

To track the progress of ongoing construction until it is brought to completion, the process of aligning three-dimensional point cloud data and an instance of a computer model must be repeated periodically, as described in this application. For example, a scan image can be obtained periodically and compared to a corresponding computer model of the same coordinate frame at an expected point in time of the ongoing construction.

Accordingly, the process of mapping three-dimensional point cloud data to an instance of a computer model is periodic at successive points in time. Consequently, the benefits of ensuring that ongoing construction of a three-dimensional structure does not deviate from its expected three-dimensional model are vastly outweighed by construction delays and costs that result from periodically repeating the laborious, time-consuming, and costly alignment process before even analyzing the differences between the actual and expected representations. That is, any savings that result from avoiding the need to re-work construction are negated by the costs that result from delays in construction to prepare and perform the deviation analysis. Consequently, the manual mapping process is cost-prohibitive and unsuitable for repetitive low-latency data capture for deviation analysis.

BIM is a process supported by various tools, technologies, and contracts involving the generation and management of digital representations of physical and functional characteristics of places. BIMs are computer files (often but not always in proprietary formats and containing proprietary data) which can be extracted, exchanged, or networked to support decision-making regarding a built asset. BIM software is used by individuals, businesses, and government agencies who plan, design, construct, operate, and maintain buildings and diverse physical infrastructures, such as water, refuse, electricity, gas, communication utilities, roads, railways, bridges, ports, and tunnels.

BIM organization is key for accurately tracking progress of a construction project. Metadata and structural information embedded there works as ground truth for determining how a current stage of construction compares with a planned state. Currently, adding needed metadata (i.e., making it high quality) to BIM for functional and structural object grouping is completely manual. Many construction projects cannot afford the manual methods to scale, which essentially risk overruns of both cost and time.

The disclosed technology addresses the aforementioned problems by adding metadata to a poor-quality BIM automatically through transfer learning from historical high-quality BIMs.

At 702, geometric and spatial properties of modeled objects are analyzed, along with granular metadata of historical high-quality models to train a recommender model.

At 704, the recommender model is trained to accurately predict the missing metadata of low-quality BIM objects given available information.

The high-quality BIM enables granular and accurate project monitoring for time, cost, and quality. Having access to this technology, a company can onboard customers with low-quality BIM for precise project tracking, which will result in significant benefits given most of the available BIMs are of low quality.

The technology can facilitate automated onboarding of projects. As such, customers can onboard their project for accurate tracking using a self-serve interface even with low-quality BIM.

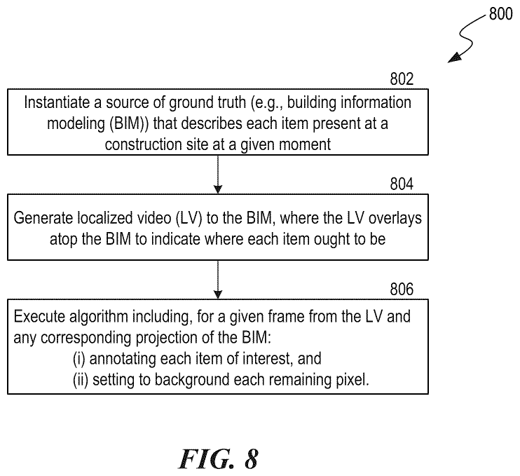

FIG. 8 is a flowchart that illustrates a method 800 for instance segmentation via BIM. The method 800 can be performed by a computing device. Instance segmentation is a technique in machine learning and computer visualization whereby each pixel of an image is assigned a category (e.g., duct, pipe, wall) and an object. This gives both entity size (area in pixels) and individual entity identification in a way that is more granular and precise than, for example, object detection.

At 802, a source of ground truth (e.g., BIM model, Doxel's onboarded translation of one) describes each item present at a construction site at a given moment (e.g., BIM).

At 804, a localized video (LV) to the BIM is provided. By overlaying the LV atop the BIM, one can see exactly where each item ought to be, especially after a machine learning/annotation pass.

At 806, the algorithm is as follows:

For a given frame from the LV and any corresponding projection of the BIM:
1. For each item of interest, annotate it.
2. For the remaining pixels, set to background.

The disclosed technique automates one of the most expensive yet powerful types of annotations in a simple way. Further, it gives sufficiently high-quality instance segmentations, annotated objects, and their position relative to the expectation from the BIM with camera intrinsic features, and matching allows for mapping to quality control via algebraic equations.

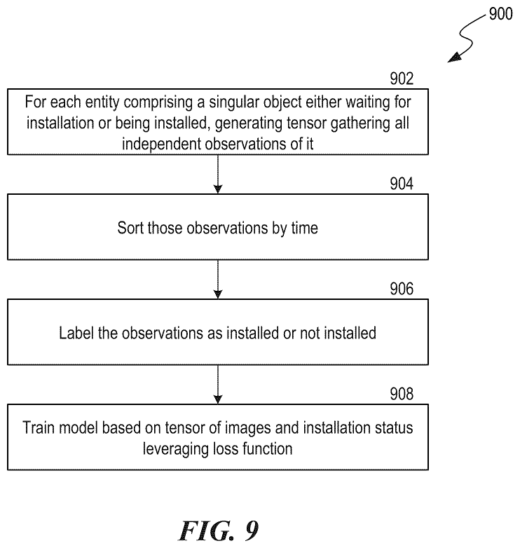

FIG. 9 is a flowchart that illustrates a method 900 for contrastive-like loss for time series.

The disclosed technology relates to an object having a state change and classifying that singular object's state change independently, per slice of time. For example, the following are each framed as classification problems: (1) a duct or vent is not installed until it is actually installed; or (2) a wall's frame is put up and then filled with insulation, then sheetrock is installed, then paint is applied.

Metric learning has become an attractive field for research in recent years. Loss functions such as contrastive loss, triplet loss, or multi-class N-pair loss have made possible generating models capable of tackling complex scenarios with the presence of many classes. Scarcity on the number of images per class not only works to build classifiers, but helps many other applications where measuring similarity is the key.

In a pure supervised learning approach, an example of a loss function is a cross-entropy loss, and each image is treated as fully independent. In particular, cross-entropy can be used to define a loss function in machine learning and optimization. The true probability is the true label and the given distribution is the predicted value of the current model.

In the disclosed technology, traditionally semi-supervised learning loss functions are used to enforce generalization across time frames to ensure understanding at an independent time slice such as triplet loss and constellation loss functions.

In the binary case, consider CIPO, which is a construction management software with customizable reporting, dashboards, document management, integration, and correspondence. In CIPO, the binary classifier is one-hot encoded and a modified version of triplet loss (one that can handle arbitrary quantities of both positive and negative cases) is used. Triplet loss is a loss function for machine learning algorithms where a reference input (called anchor) is compared to a matching input (called positive) and a non-matching input (called negative). The system minimizes the distance from the anchor to the positive input, and maximizes the distance from the anchor to the negative input.

In the n-state problem, the loss is constellation. A constellation loss metric is where the distances among all class combinations are simultaneously learned. Constellation loss is a function that optimizes a deep learning classifier with very few training images. Constellation loss goes one step further than other loss functions by simultaneously learning distances among all class combinations. Constellation loss can attract same class image embeddings while pulling apart the rest of the classes, all at the same time. This way, an optimal embedding or descriptor of the image is generated.

For example, in the binary case:

At 902, for each entity (defined as a singular thing either waiting for installation or that is installed), gather all independent observations of it.

At 904, sort those observations by time.

At 906, label the observations as installed (0,1) or not installed (1,0).

At 908, train a model on this tensor of images and installation status leveraging the loss function described above using the usual techniques.

This loss function improves accuracy and generalization capabilities across time (e.g., the first time you look at an area where something is happening at a construction site vs. the last time), meaning annotators no longer have to keep labeling the first elements on a site before machine learning is started. This lowers new site costs and gives the company a competitive edge. The disclosed technology could be used in CIPO classifier training.

### EXAMPLES

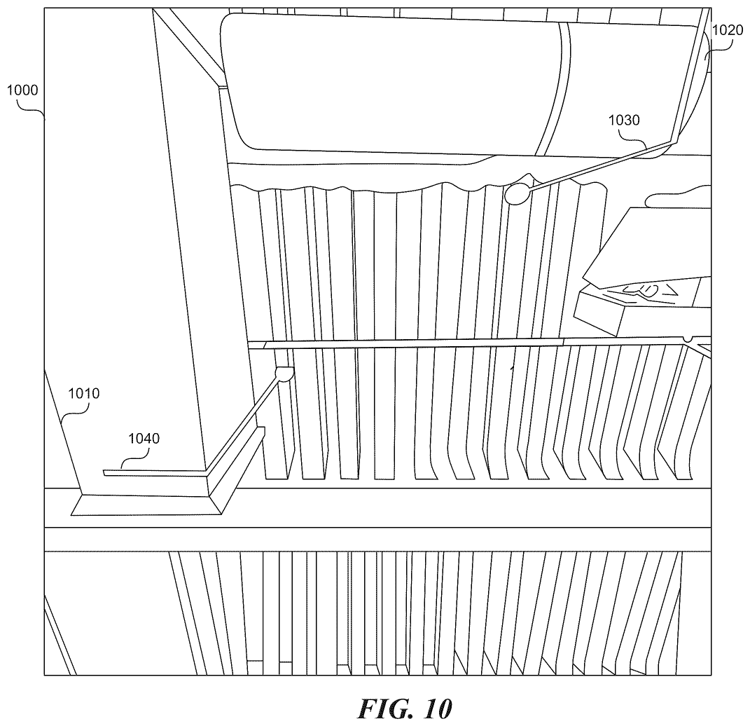

FIG. 10 shows a recording 1000 of a construction site. The recording 1000 can be a recording including an image as shown in FIG. 10, a point cloud, a panorama, etc. The recording 1000 can be one representation, such as an initial recording, or a temporal sequence of recordings. For example, the recording 1000 can be an initial image, e.g., frame, or a subsequent image, e.g., frame, in a video, recorded when a camera traverses the trajectory 340 in FIG. 3A. In addition to being an image, the recording 1000 can be a point cloud, a panorama, etc.

The recording 1000 can show various physical objects at the construction site such as a duct 1010, a pipe 1020, and supports 1030, 1040 (only two labeled for brevity). The disclosed system, as described in this application, can identify in the recording 1000 the various objects 1010, 1020, 1030, 1040.

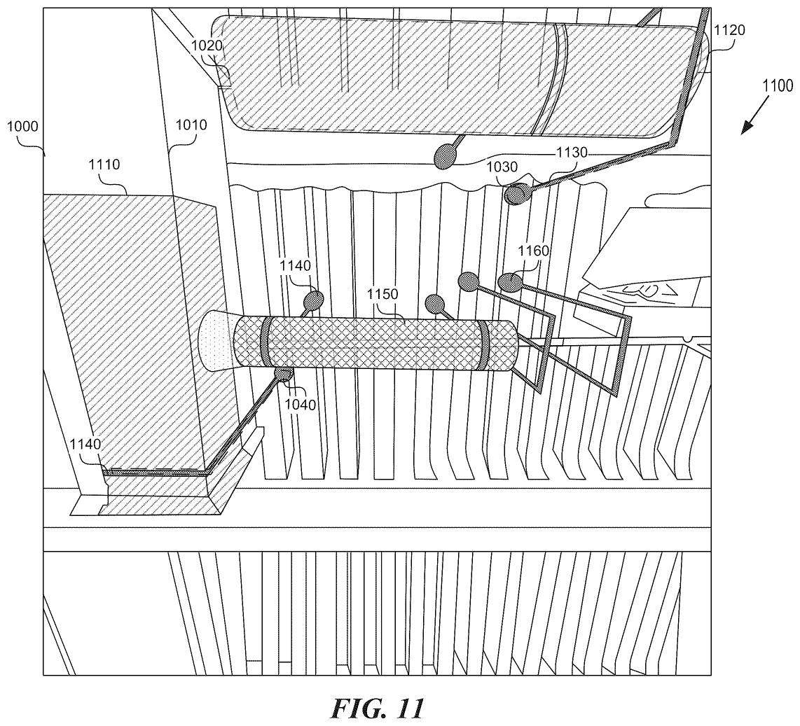

FIG. 11 shows a mapping 1100 between a recording 1000 of objects at a construction site and virtual objects in a three-dimensional computer model 320 in FIG. 3A. As described in this application, the recording 1000 can be an image, a point cloud, a panorama, and/or a temporal sequence of such recordings.

In addition to identifying the physical object 1010, 1020, 1030, 1040 visible in the recording 1000, the system can identify a corresponding virtual object 1110, 1120, 1130, 1140. The corresponding virtual object 1110, 1120, 1130, 1140 can be an object in the three-dimensional computer model 320.

The physical objects 1010, 1020, 1030, 1040 can be at different stages of completion at the construction site 305 in FIG. 3A. For example, object 1010 can be a duct, and can be at the final stage of completion along with the support 1040. Object 1120 can be a pipe which can be installed along with the support 1030, however the pipe may not be bolted and may not be insulated. Consequently, the completed stages of the pipe 1120 construction can include that the installation has started, the support is installed, and the pipe is in position, but the stages “bolted” and “insulated” are not completed.

The construction of virtual objects 1150, 1160 may not have been started. For example, virtual object 1150 can be a pipe and virtual object 1160 (only one labeled for brevity) can be a support for the pipe. The virtual object 1150, 1160 can exist in the three-dimensional computer model 320, however the object may not be visible in the recording 1000. In that case, the system can determine that the stage of construction of virtual object 1150, 1160 is not started.

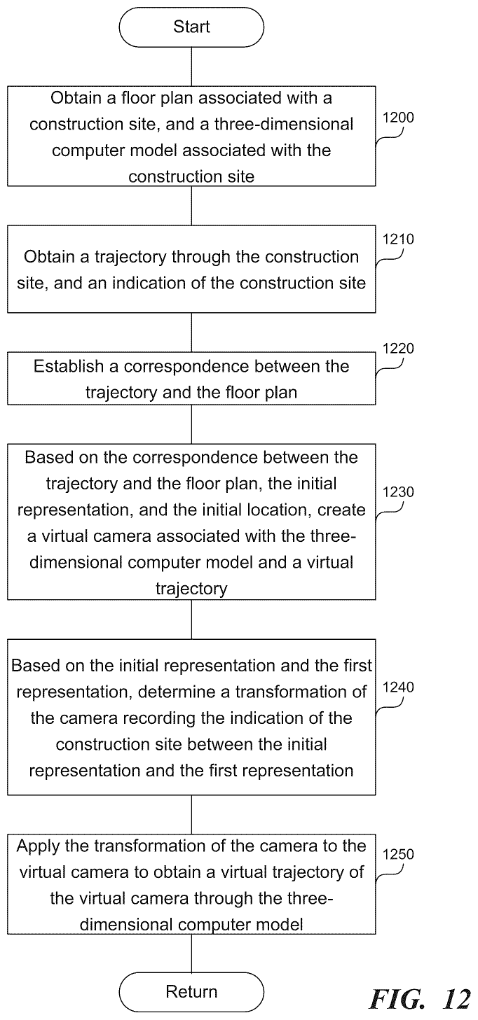

FIG. 12 is a flowchart of a method to establish a correspondence between a construction site and a three-dimensional computer model of the construction site. A hardware or software processor executing instructions described in this application can, in step 1200, obtain a floor plan 380 in FIG. 3A associated with a construction site 305 in FIG. 3A, and a three-dimensional computer model 320 in FIG. 3A associated with the construction site, where the floor plan represents a two-dimensional projection of the three-dimensional computer model associated with the construction site. The floor plan 380 and the three-dimensional computer model 320 can be part of a BIM model.

In step 1210, the processor can obtain a trajectory 340 in FIG. 3A through the construction site 305, and a recording 1000 in FIG. 10 of the construction site 305. The recording 1000 can include a first object at the construction site 305 and can be in the form of a video associated with the construction site, a panorama associated with the construction site, a point cloud associated with the construction site, etc. The recording 1000 can include a temporal sequence of representations including an initial representation indicating a beginning of the recording and a first representation following the initial representation. The trajectory 340 can indicate a path of a physical camera 350 in FIG. 3A recording the recording 1000 of the construction site 305.

In step 1220, the processor can establish a correspondence 390 in FIG. 3A between the trajectory 340 and the floor plan 380, where the correspondence indicates how a location 342 on the trajectory corresponds to a location 382 on the floor plan. The correspondence 390 can indicate an initial location 315 in FIG. 3A associated with the trajectory 340 that corresponds to the initial representation, e.g., the view 310 in FIG. 3A.

In step 1230, based on the correspondence between the trajectory 340 and the floor plan 380, the initial representation (view) 310, and the initial location 315, the processor can create a virtual camera 355 in FIG. 3A associated with the three-dimensional computer model 320 and a virtual trajectory 345 in FIG. 3A, where the virtual trajectory influences multiple virtual objects 365, 375 in FIG. 3A visible to the virtual camera. The multiple virtual objects 365, 375 visible to the virtual camera 355 match multiple objects 360, 370 in FIG. 3A visible in the initial representation (view) 310. The virtual trajectory 345 can specify not only position of the virtual camera 355, but also the virtual camera's view frustrum, through specifying rotation, pitch, yaw, and roll, thus determining the virtual objects 365, 375 visible to the virtual camera 355. The virtual camera 355 can be a 360° camera capable of generating a panorama, or a non-360° camera.

In step 1240, based on the initial representation and the first representation, the processor can determine a transformation of the physical camera 350 recording the recording of the construction site 305 between the initial representation and the first representation. The transformation can include a rigid and a nonrigid transformation. The rigid transformation can include translation and rotation, while the nonrigid transformation can include changing the view frustrum of the camera, such as changing the focal length of the lens. The processor can use the pose graph optimization, as described in this application, to determine the transformation between the initial representation and the first representation.

In step 1250, the processor can apply the transformation of the physical camera 350 to the virtual camera 355 to obtain a virtual trajectory 345 of the virtual camera 355 through the three-dimensional computer model 320, where the virtual trajectory of the virtual camera corresponds to the trajectory 340 of the physical camera 350. To determine the transformation of the virtual camera 355, the processor can use pose graph optimization. As explained in this application, in pose graph optimization, the processor aims to find the best set of poses that satisfy one or more constraints as closely as possible. The system achieves this by minimizing a global error function, which measures the difference between the observed constraints and the predicted constraints based on the current pose estimates. In this case, the constraint can be the visual difference between the physical objects 360, 370 in FIG. 3A that are visible to the physical camera 350, and the virtual objects 365, 375 in FIG. 3A that are visible to the virtual camera 355. In other words, the pose graph optimization can configure the virtual camera 355 to minimize the visual difference between the objects.

To determine the virtual objects 365, 375 that are visible in the recording 330 in FIG. 3A of the physical construction site 305, the processor can obtain multiple vectors representing multiple appearances of multiple virtual objects 365, 375 in the three-dimensional computer model 320 associated with the construction site 305, where the multiple vectors include multiple clusters of vectors. A cluster of vectors among the multiple clusters of vectors can represent a virtual object 365, 375 viewed from multiple, e.g., various, angles.

The processor can compute each centroid of each cluster among the multiple clusters of vectors to obtain multiple centroids. A particular centroid represents a particular object in the three-dimensional computer model.

To determine a first object 360, 370 present in the first frame of the recording 330, the processor can perform the following steps. First, the processor can obtain a first vector representing an appearance of the first object associated with the recording. The vector can be embedded in multidimensional space, where the distance between vectors indicates similarity between objects. In other words, the lower the distance, the more similar are the objects represented by the vectors. Second, the processor can determine whether the first vector matches a centroid among the multiple centroids within a predetermined threshold. To determine the similarity between two multidimensional vectors, the processor can measure the angle between the two vectors using cosine similarity, and the predetermined threshold of similarity can be 0.6 or higher. Third, upon determining that the first vector matches the centroid among the multiple centroids, the processor can determine that the first object 360, 370 associated with the recording 330 corresponds to a virtual object 365, 375 represented by the centroid among the multiple centroids. However, upon determining that the first vector does not match the centroid among the multiple centroids, the processor can determine that the first object 360, 370 associated with the recording 330 is not included among the multiple virtual objects 365, 375.

More generally, to determine the virtual objects 365, 375 that are visible in the recording 330, the processor can extract features from the recording using the following steps. First, the processor can obtain multiple vectors representing multiple appearances of multiple virtual objects 365, 375 in the three-dimensional computer model 320 associated with the construction site 305, where a vector among the multiple vectors corresponds to a virtual object 365, 375 among the multiple objects. Second, the processor can obtain a first vector representing an appearance of an object 360, 370 associated with the recording 330. The processor can obtain the first vector from a machine learning classifier. Third, the processor can determine whether the first vector matches the vector among the multiple vectors within a predetermined threshold, such as 0.5 or higher. Fourth, upon determining that the first vector matches the vector among the multiple vectors, the processor can determine that the object 360, 370 associated with the recording 330 corresponds to the virtual object 365, 375 among the multiple objects. However, upon determining that the first vector does not match the vector among the multiple vectors, the processor can determine that the object 360, 370 associated with the recording 330 is not included among the multiple objects.

The processor can obtain a second recording of the construction site 305 captured at a time different from a capture time associated with the recording 330, where the second recording includes a second sequence of representations including a second initial representation indicating a beginning of the second recording and a second representation following the second initial representation, and where the second sequence of representations is different from the first sequence of representations. The representation can be an image, a panorama, a point cloud, etc. The second sequence can be recorded at the same construction site 305 as the first sequence, however the second sequence can be recorded by a robot 1 in FIG. 1, traveling along a different trajectory than the trajectory 340. The processor can map the images between the two sequences using an efficient tree data structure, which can be a spatial tree data structure such as an octave tree. Specifically, the processor can create a first tree data structure representing the sequence of representations. The processor can create a second tree data structure representing the second sequence of representations. The processor can establish a correspondence between the first tree data structure and the second tree data structure by mapping the second representation associated with the second sequence of representations to an initial representation (view) 310 in FIG. 3A in the sequence of representations. Specifically, the processor can search the first tree data structure for the representation in the sequence of representations similar to the second representation more efficiently than searching by comparing the second representation to each representation in the sequence of representations. The searching for representations using the tree structure can be increased from N² (where N is the number of representations in the sequence) to N*log_{base} N where the base of the log depends on the number of branches of the tree. If the tree structure is a binary tree structure, the base is equal to 2. If, however, the tree structure is an octave tree structure, the base can be 8, thus drastically increasing the efficiency of the search.

The processor can track progress of the construction site by matching two different sequences of representations. Specifically, the processor can obtain a second recording of the construction site 305 captured at a time different from a capture time associated with the recording 330. The second time can be a later time, thus representing a later stage of progress of the construction at the construction site 305.

The processor can extract features from the indication and the second recording described in this application, by matching vector representations of the physical objects 360, 370 and the virtual objects 365, 375. For example, the processor can use the clustering technique described in this application. In another example, the processor can obtain multiple vectors representing multiple appearances of multiple virtual objects 365, 375 in the three-dimensional computer model 320 associated with the construction site 305, where a vector among the multiple vectors corresponds to a virtual object 365, 375 among the multiple objects. The processor can obtain a first vector representing an appearance of a first object associated with the recording and a second vector representing an appearance of a second object associated with the second recording. The processor can determine whether the first vector matches the vector among the multiple vectors within a first predetermined threshold. The processor can determine whether the second vector matches the vector among the multiple vectors within a second predetermined threshold. The second predetermined threshold can be higher than the first predetermined threshold because the second vector can represent a later stage of construction of an object, and thus the second vector can more closely resemble the vector which represents a completed virtual object 365, 375. For example, the second predetermined threshold can be 0.7 or higher. Upon determining that the first vector matches the vector among the multiple vectors, and that the second vector matches the vector among the multiple vectors, the processor can determine that the first object associated with the recording and the second object associated with the second recording correspond to the same virtual object 365, 375 among the multiple objects. The processor can determine a difference between the first object associated with the recording and the second object associated with the second recording. The difference can include increased size of the object, addition of supports, addition of bolts, addition of insulation, etc. Based on the difference, the processor can determine progress associated with the construction site 305, such as whether the object has been installed, whether support has been installed, whether the object is in position, whether the object is bolted, and/or whether the object is insulated.

The processor can create training data for artificial intelligence. The processor can extract features from the recording 330 in various ways as described in this application. For example, the processor can obtain multiple vectors representing multiple appearances of multiple virtual objects 365, 375 in the three-dimensional computer model 320 associated with the construction site 305, where a vector among the multiple vectors corresponds to a virtual object 365, 375 among the multiple objects. The processor can obtain a first vector representing an appearance of an object 360, 370 associated with the recording 330. The processor can determine whether the first vector matches the vector among the multiple vectors within a predetermined threshold. Upon determining that the first vector matches the vector among the multiple vectors, the processor can create a map between an indication of the object 360, 370 associated with the indication and an indication of the virtual object 365, 375 among the multiple objects. The processor can provide the map to an artificial intelligence to use in training the artificial intelligence to identify the multiple objects based on a second recording. Once trained, the artificial intelligence can take in a recording 330 of the construction site 305, and identify the object in the recording, without using the dimensional computer model 320, such as a BIM model.

The processor can obtain a recording 330 of geometry representing the construction site 305 obtained along the trajectory 340 through the construction site. Based on the virtual trajectory 345 of the virtual camera 355, the processor can establish a mapping between the recording 330 of geometry and the three-dimensional computer model 320, where the three-dimensional computer model represents the construction site at completion. Based on the mapping between the recording 330 of geometry and the three-dimensional computer model 320, the processor can determine a difference between the recording 330 of geometry and the three-dimensional computer model 320. Based on the difference, the processor can determine progress associated with the construction site 305, such as whether the object 360, 370 has been installed, whether support has been installed, whether the object is in position, whether the object is bolted, whether the object is insulated, etc.

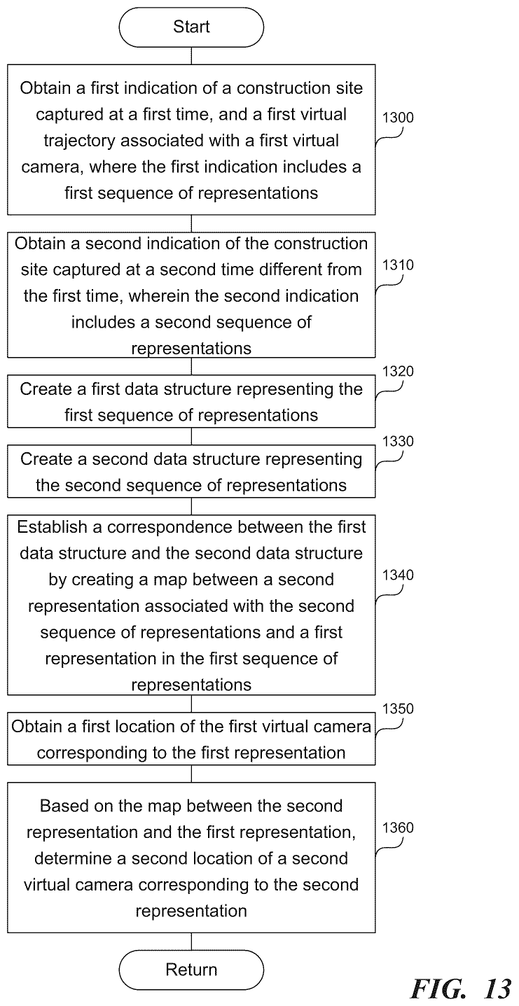

FIG. 13 is a flowchart of a method to determine correspondence between two videos of a construction site, taken at two different times, where the correspondence can be used for construction site monitoring. A hardware or software processor performing instructions described in this application can in step 1300 obtain a first recording 330 in FIG. 3A of a construction site 305 in FIG. 3A captured at a first time, and a first virtual trajectory 345 in FIG. 3A associated with a first virtual camera 355 in FIG. 3A, where the first recording includes a first sequence of representations including a first initial representation indicating a beginning of the first recording and a first representation following the first initial representation. The first virtual trajectory 345 indicates a path of the first virtual camera 355 through a three-dimensional computer model 320 of the construction site 305, where an indication recorded by the first virtual camera 355 moving along the first virtual trajectory 345 corresponds to the first recording 330 recorded at the construction site 305. The first recording 330 can be the reference dataset as described in this application.

In step 1310, the processor can obtain a second recording of the construction site 305 captured at a second time different from the first time, where the second recording includes a second sequence of representations including a second initial representation indicating a beginning of the second recording and a second representation following the second initial representation, and where the second sequence of representations is different from the first sequence of representations. The second recording can be the query dataset as described in this application.

In step 1320, the processor can create a first data structure representing the first sequence of representations. The first data structure can be a tree structure subdividing space using k-d trees, or oct-trees.

In step 1330, the processor can create a second data structure representing the second sequence of representations.

In step 1340, the processor can establish a correspondence between the first data structure and the second data structure by creating a map between the second representation associated with the second sequence of representations and a first representation in the first sequence of representations. To create the map, the processor can search the first data structure for the first representation in the first sequence of representations similar to the second representation more efficiently than searching by comparing the second representation to each representation in the first sequence of representations. As described in this application, the search can be logarithmically more efficient than a brute force search.

In step 1350, the processor can obtain a first location of the first virtual camera 355 in FIG. 3A corresponding to the first representation. The location can include the location and orientation of the first virtual camera 355.

In step 1360, based on the map between the second representation and the first representation, the processor can determine a second location of a second virtual camera corresponding to the second representation. The second location of the second virtual camera indicates multiple objects in the three-dimensional computer model 320 in FIG. 3A of the construction site 305, where the multiple objects are visible to the second virtual camera.

To obtain the first recording 330 of the construction site 305 captured at the first time, and the first virtual trajectory 345 associated with the first virtual camera 355, the processor can obtain a floor plan 380 in FIG. 3A associated with a construction site 305, and a three-dimensional computer model 320 associated with the construction site. The floor plan 380 represents a two-dimensional projection of the three-dimensional computer model 320 associated with the construction site 305. The floor plan 380 can be part of the BIM model. The processor can obtain a trajectory 340 through the construction site 305, and the first recording 330 of the construction site, where the trajectory indicates a path of a physical camera 350 making the first recording of the construction site. The first recording 330 includes a sequence of representations including a first initial representation indicating a beginning of the first recording and a first representation following the first initial representation. The representation can be an image, a panorama, a point cloud, etc. The processor can establish a correspondence 390 between the trajectory 340 and the floor plan 380, where the correspondence indicates how a location 342 on the trajectory corresponds to a location on the floor plan 380, and where the correspondence indicates an initial location 315 associated with the trajectory that corresponds to the first initial representation. Based on the correspondence 390 between the trajectory 340 and the floor plan 380, the first initial representation, and the initial location 315, the processor can create a virtual camera 355 associated with the three-dimensional computer model 320 including a position and a rotation. The position and the orientation of the virtual camera 355 in the three-dimensional computer model 320 determines virtual objects 365, 375 associated with a three-dimensional computer model 320 visible to the virtual camera 355, where the objects visible to the virtual camera match objects visible in the first initial representation. The virtual camera 355 can be a 360° camera, or a non-360° camera. Based on the first initial representation and the first representation, the processor can determine a transformation of the physical camera 350 making the first recording 330 of the construction site 305 between the first initial representation and the first representation, where the first representation immediately follows the first initial representation in the first sequence of representations. The processor can apply the transformation of the physical camera 350 to the virtual camera 355 to obtain a virtual trajectory 345 of the virtual camera associated with the three-dimensional computer model, where the virtual trajectory of the virtual camera corresponds to the trajectory 340 of the camera. To calculate the transformation of the physical camera 350, the processor can use pose graph optimization, described in this application.

The processor can obtain multiple vectors representing multiple appearances of multiple virtual objects 365, 375 in the three-dimensional computer model 320 associated with the construction site 305, where the multiple vectors include multiple clusters of vectors. A cluster of vectors among the multiple clusters of vectors represents a virtual object 365, 375 in the three-dimensional computer model 320 associated with the construction site 305 viewed from multiple angles. The processor can compute each centroid of each cluster among the multiple clusters of vectors to obtain multiple centroids, where a particular centroid represents a particular object in the three-dimensional computer model 320. The processor can determine a first object present in the second frame of the second recording by performing the following steps. First, the processor can obtain a first vector representing an appearance of the first object associated with the second recording. Second, the processor can determine whether the first vector matches a centroid among the multiple centroids within a predetermined threshold. Third, upon determining that the first vector matches the centroid among the multiple centroids, the processor can determine that the first object associated with the second recording corresponds to an object represented by the centroid among the multiple centroids. However, upon determining that the first vector does not match the centroid among the multiple centroids, the processor can determine that the first object associated with the second recording is not included among the multiple objects.

The processor can extract features from the second recording by performing the following steps. First, the processor can obtain multiple vectors representing multiple appearances of multiple virtual objects 365, 375 in the three-dimensional computer model 320 associated with the construction site 305, where a vector among the multiple vectors corresponds to an object among the multiple objects. Second, the processor can obtain a first vector representing an appearance of an object associated with the second recording. Third, the processor can determine whether the first vector matches the vector among the multiple vectors within a predetermined threshold. Upon determining that the first vector matches the vector among the multiple vectors, the processor can determine that the object associated with the second recording corresponds to the object among the multiple objects. Upon determining that the first vector does not match the vector among the multiple vectors, the processor can determine that the object associated with the second recording is not included among the multiple objects.

The processor can track progress of construction at the construction site 305 by extracting features from the first recording and the second recording using the following steps. First, the processor can obtain multiple vectors representing multiple appearances of multiple virtual objects 365, 375 in the three-dimensional computer model 320 associated with the construction site 305, wherein a vector among the multiple vectors corresponds to an object among the multiple objects. Second, the processor can obtain a first vector representing an appearance of a first object 360, 370 associated with the first recording 330 and a second vector representing an appearance of a second object associated with the second recording. Third, the processor can determine whether the first vector matches the vector among the multiple vectors within a first predetermined threshold. Fourth, the processor can determine whether the second vector matches the vector among the multiple vectors within a second predetermined threshold. The second threshold can be higher than the first threshold, thus indicating a better match between the second object and the virtual object 365, 375, indicating a completed version of the second object, than the match between the first object and the virtual object 365, 375. The better match can be due to progressing construction where the second object is closer to being complete than the first object. Fifth, upon determining that the first vector matches the vector among the multiple vectors, and that the second vector matches the vector among the multiple vectors, the processor can determine that the first object associated with the first recording and the second object associated with the second recording correspond to the object among the multiple objects.

Upon determining that the first object and the second object correspond to the same object, the processor can determine a difference between the first object associated with the recording and the second object associated with the second recording. Based on the difference, the processor can determine progress associated with the construction site, such as whether the object has been installed, whether support has been installed, whether the object is in position, whether the object is bolted, whether the object is insulated, etc.

The processor can extract features from the second recording by performing the following steps. First, the processor can obtain multiple vectors representing multiple appearances of multiple objects 360, 370 in the three-dimensional computer model 320 associated with the construction site 305, wherein a vector among the multiple vectors corresponds to an object among the multiple objects. Second, the processor can obtain a first vector representing an appearance of an object associated with the second recording. Third, the processor can determine whether the first vector matches the vector among the multiple vectors within a predetermined threshold. Upon determining that the first vector matches the vector among the multiple vectors, the processor can create a map between an indication of the object associated with the second recording and an indication of the object among the multiple objects. The processor can provide the map to an artificial intelligence to use in training the artificial intelligence to identify the multiple objects based on a second recording.

The processor can obtain a recording 330 of geometry representing the construction site 305 obtained along the trajectory 340 through the construction site. Based on the virtual trajectory 345 of the virtual camera 355, the processor can establish a mapping between the recording 330 of geometry and the three-dimensional computer model 320, where the three-dimensional computer model represents the construction site at completion. Based on the mapping between the recording 330 of geometry and the three-dimensional computer model 320, the processor can determine a difference between the recording 330 of geometry and the three-dimensional computer model 320. Based on the difference, the processor can determine progress associated with the construction site 305, such as whether the object has been installed, whether support has been installed, whether the object is in position, whether the object is bolted, whether the object is insulated, etc.

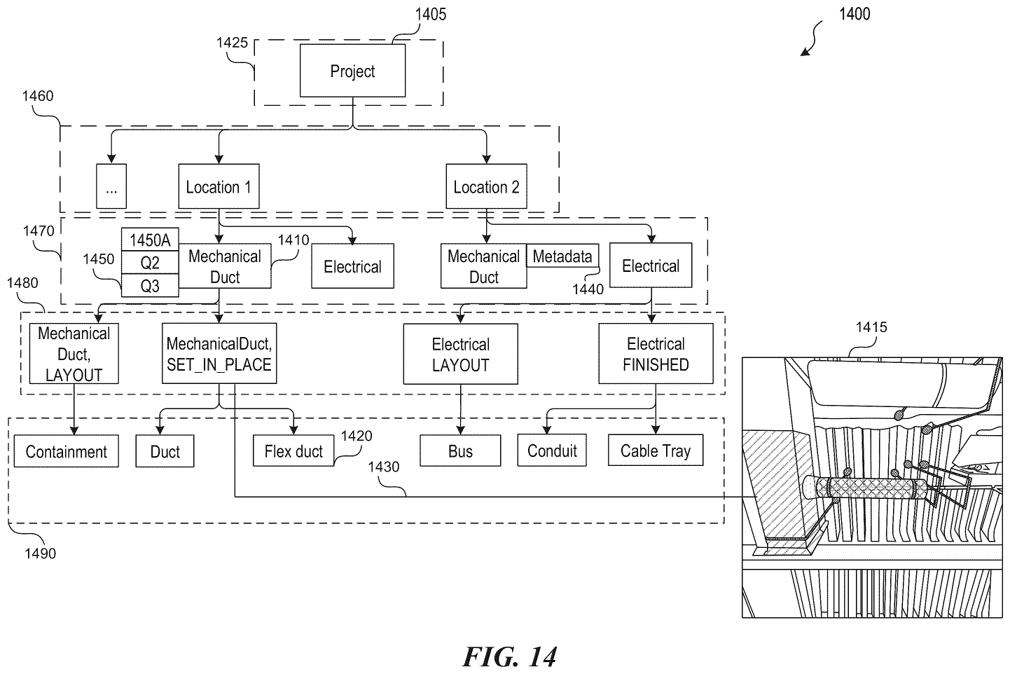

FIG. 14 shows a hierarchy of objects present at a construction site. The hierarchy 1400 can be a canonical hierarchy applicable to objects present at multiple construction sites 305 in FIG. 3A. The hierarchy can include multiple levels 1425, 1460, 1470, 1480, 1490. The hierarchy 1400 can be a hierarchical data structure.

The initial level 1425 can include a single node 1405 that is the root of the entire hierarchy 1400, and a parent to all the nodes 1410, 1420 (only two labeled for brevity) included in the hierarchy. The initial level 1425 can indicate the name of the project.

The subsequent level 1460 can indicate a location at the construction site 305. The second subsequent level 1470 can indicate the function of the child levels 1480, 1490, such as mechanical duct, electrical, foundation, hot water, cold water, etc.

The third subsequent level 1480 can indicate the stage of construction such as layout, set in place, finished, insulated, supports installed, etc. The stage of construction can depend on the function of the parent in the second subsequent level 1470. As can be seen in FIG. 14, when the parent node 1410 is mechanical duct, the stages of construction can be layout and set in place, while when the parent is electrical, the stages of construction can include layout and finished.

The fourth subsequent level 1490 can indicate the objects that are needed for the corresponding stage of construction to be considered complete. For example, for the mechanical duct layout stage to be complete, containment needs to be installed. For the mechanical duct set in place stage to be complete, the duct and the flex duct need to be installed. For the electrical layout stage to be complete, the bus needs to be installed, while for the electrical finished stage to be complete, the conduit and cable tray need to be installed.

The hierarchy 1400 can include a parent node 1405, 1410 and child node 1410, 1420 (only three labeled for brevity). The node 1405 can be the parent node of all the rest of the nodes, and thus the root node of the whole hierarchy 1400. The node 1405 does not have any parent nodes and thus is not a child node. The node 1410 has both a parent node and child nodes, and thus can be both a parent node and a child node. The node 1420 is a leaf node, and like all other leaf nodes in the fourth subsequent level 1490 has no children, thus the child node 1420 cannot be a parent node.

The hierarchy 1400 can include or be associated with a map 1430 between the hierarchy and a computer model 1415 of the construction site 305. The map 1430 can establish a correspondence between a node 1405, 1410, 1420 and the hierarchy 1400, and the computer model 1415.

In addition, the hierarchy 1400 can include metadata 1440. The metadata 1440 can be present at each node 1405, 1410, 1420 of the hierarchy 1400. The metadata 1440 can specify additional aspects of the associated nodes 1405, 1410, 1420 such as gauge of the object, size of the object such as 2-inch or 4-inch, type of the object such as metal, plastic, copper, iron, etc.

The hierarchy 1400 can include multiple questions 1450 (only one labeled for brevity). Each node 1405, 1410, 1420 in the hierarchy 1400 can be associated with its own instance of the multiple questions 1450. Each question 1450A among the multiple questions requests an indication of a stage of construction associated with the object. For example, the questions can ask in order:
1. Has the construction of the object started?
2. Has the support for the object been installed?
3. Is the object in position?
4. Is the object bolted?
5. Is the object insulated?

The questions can be sequential, and a no answer to one of the questions indicating that the stage is not complete can imply that the answer to the rest of the questions in the sequence is also negative. Therefore, once the system receives a negative answer to one of the questions, for efficiency, the system can cease asking subsequent questions.

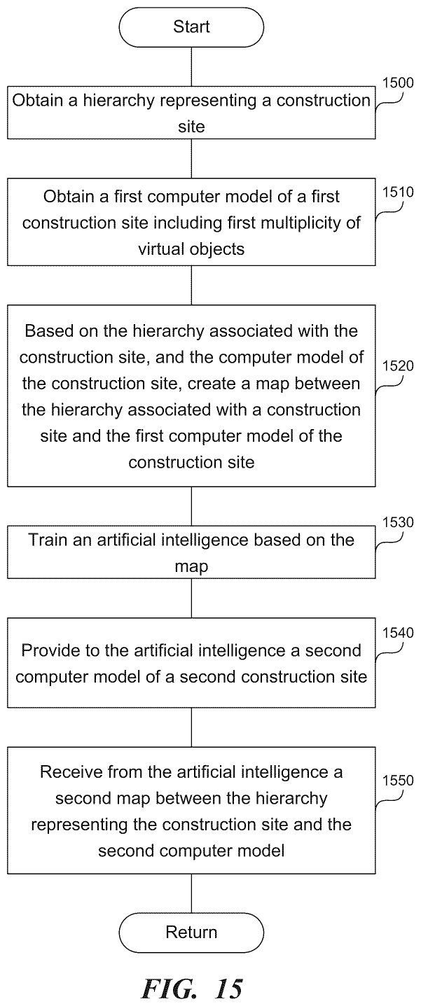

FIG. 15 is a flowchart of a method to use an artificial intelligence to establish a map between objects in a computer model of a construction site and a hierarchy of models of the construction site. A hardware or software processor executing instructions described in this application can in step 1500 obtain a hierarchy 1400 in FIG. 14 representing a construction site 305 in FIG. 3A, where the hierarchy includes a parent node 1410 in FIG. 14 and a child node 1420 in FIG. 14. The parent node 1410 can indicate a function associated with an object at the construction site, such as cold water, hot water, electrical, mechanical duct, structural, etc. The child node 1420 can indicate an object type associated with the object at the construction site, where the object type can be pipe, insulation, concrete, electrical wire, containment, duct, flex duct, bus, conduit, cable tray, etc.

In step 1510, the processor can obtain a first three-dimensional computer model 320 in FIG. 3A of a first construction site 305 including a first multiplicity of virtual objects 365, 375 in FIG. 3A, where a first virtual object 365, 375 among the first multiplicity of virtual objects corresponds to a first object 360, 370 in FIG. 3A at the first construction site 305. In other words, the first object 360, 370 represents the current stage of construction of the virtual object 365, 375, while the virtual object 365, 375 represents the object when the construction is complete. The first three-dimensional computer model 320 can be a multidimensional computer model, a BIM model, or any suitable virtual representation of a construction site 305.

In step 1520, based on the hierarchy 1400 associated with the construction site 305, and the three-dimensional computer model 320 of the construction site, the processor can create a first map 1430 between the hierarchy associated with the construction site and the first computer model of the construction site.

In step 1530, the processor can train an artificial intelligence based on the first map 1430.

In step 1540, the processor can provide to the artificial intelligence a second computer model of a second construction site, where the second computer model is different from the first three-dimensional computer model 320. The first computer model can be represented as a first building information model, and the second computer model can be represented as a second building information model.

In step 1550, the processor can receive from the artificial intelligence a second map between the hierarchy 1400 representing the construction site and the second computer model.

The processor can use the first map 1430 and the hierarchy 1400 to transfer attributes missing from the first three-dimensional computer model 320, such as metadata 1440, to the hierarchy 1400 nodes 1410, 1420. The processor can obtain a first three-dimensional computer model 320 of the first construction site 305 including multiple virtual objects 365, 375, where the first computer model includes first metadata 1440 associated with the first virtual object. The processor can determine a location of the first virtual object 365, 375 in the hierarchy 1400 representing the construction site 305. The location of the first virtual object 365, 375 in the hierarchy 1400 can be represented using the identifier of the child node 1420, corresponding to the first virtual object 365, 375, or the location can be represented using the identifiers of the parent nodes 1410 of the child node 1420. Finally, the processor can associate the first metadata 1440 with the location of the first virtual object in the hierarchy representing the construction site.

The processor can use the first map, the second map, and the hierarchy 1400 to complete attributes missing from the second computer model, such as metadata 1440. For example, the first and the second computer model can be part of two different BIM models, which can include metadata 1440, a floor plan 380 in FIG. 3A, etc. The processor can obtain a first three-dimensional computer model 320 of the first construction site 305 including multiple virtual objects 365, 375, where the first computer model includes first metadata 1440 associated with the first virtual object 365, 375. The processor can determine a first location of the first virtual object 365, 375 in the hierarchy 1400 representing the construction site 305. The processor can associate the first metadata 1440 with the first location of the first virtual object 365, 375 in the hierarchy 1400 representing the construction site 305. The processor can obtain the second computer model of the second construction site, where the second computer model includes a second virtual multiplicity of virtual objects, and where a second virtual object among the second multiplicity of virtual objects does not include metadata 1440. Based on the second map, the processor can obtain a second location of the second virtual object in the hierarchy 1400 representing the construction site 305, which can be the same as the first location. Based on the second location, the processor can retrieve from the hierarchy representing the construction site metadata 1440 associated with the second location, which can be the same as metadata associated with the first location, thereby augmenting the second computer model with missing metadata 1440.

The processor can obtain a first three-dimensional computer model 320 of the first construction site 305 including multiple virtual objects 365, 375 where the first computer model includes first metadata 1440 associated with the first virtual object 365, 375, and where the metadata includes size associated with the first virtual object or type associated with the first virtual object. The processor can determine a location of the first virtual object 365, 375 in the hierarchy 1400 representing the construction site 305. The processor can associate the first metadata 1440 with the location of the first virtual object 365, 375 in the hierarchy 1400 representing the construction site 305.

The processor can assign multiple questions 1450 associated with a node 1410, 1420 in the hierarchy 1400 representing the construction site 305, where a question 1450 among the multiple questions requests an indication of a stage of construction associated with the object 360, 370 at the construction site 305 represented by the node. The question 1450 among the multiple questions requests an answer from a binary set, such as a binary set including yes or no answers.

In one example, the processor can receive a recording 330 in FIG. 3A, e.g., a video or a point cloud, and ask binary classification questions about the recording. The processor can obtain multiple questions 1450 associated with a node 1410, 1420 in the hierarchy 1400 representing the first construction site, where a question among the multiple questions requests an indication of a stage of construction associated with a first object 360, 370 represented by the node 1410, 1420, and where the question 1450 among the multiple questions requests an answer from a binary set, such as a binary set including yes or no answers, or 0 or 1 answers. The processor can obtain a recording 330 of a first object 360, 370 at the first construction site 305. The processor can present the multiple questions to a user. The processor can receive the answer associated with the binary set from the user. Finally, the processor can create an artificial intelligence training dataset based on the answer associated with the binary set and the recording of the first object at the first construction site. In addition, the processor can provide a recording 330 of a construction site 305 to the artificial intelligence, and ask for the state of the construction.

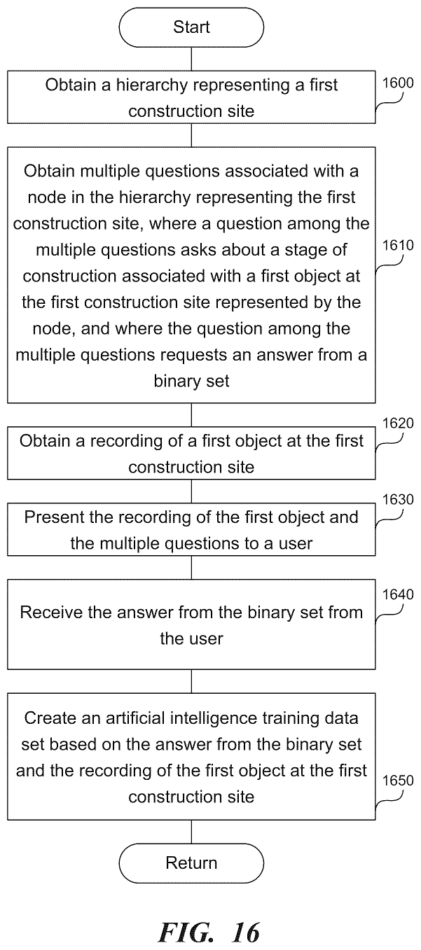

FIG. 16 is a flowchart of a method to train and use an artificial intelligence to determine progress of construction at a construction site. A hardware or software processor executing instructions described in this application can in step 1600 obtain a hierarchy 1400 in FIG. 14 representing a first construction site 305 in FIG. 3A, where the hierarchy 1400 includes a parent node 1410 in FIG. 14 and a child node 1420 in FIG. 14. The parent node 1410 can indicate a function, e.g., cold water, hot water, foundation, frame, electrical, mechanical duct, etc., associated with an object 360, 370 in FIG. 3A at the construction site 305 and the child node 1420 can indicate an object type associated with the object at the first construction site. The object type can be a 2-inch copper pipe, 2×4 stud, drywall, containment, duct, flex duct, bus, conduit, cable tray, etc.

In step 1610, the processor can obtain multiple questions 1450, e.g. queries, associated with a node 1410, 1420 in the hierarchy 1400 representing the first construction site. A question 1450 among the multiple questions can ask about a stage of construction associated with a first object 360, 370 at the first construction site 305 represented by the node 1410, 1420. The question 1450 among the multiple questions can request an answer from a binary set, such as a binary set including yes or no answers, or 0 or 1 answers, e.g. indications. The question 1450 requesting a binary answer is easy for a user to answer as opposed to a question requesting a more complicated answer. For example, answering the question 1450 “Is the pipe insulated?” is easier than answering the question “What is the stage of the construction of the pipe?” because the latter question requires more knowledge on the part of the user.

In step 1620, the processor can obtain a recording 330 in FIG. 3A of a first object 360, 370 at the first construction site 305. The recording 330 can be a video, an image, a panorama, a point cloud, etc.

In step 1630, the processor can present the recording 330 of the first object 360, 370 and the multiple questions to a user.

In step 1640, the processor can receive the answer associated with the binary set from the user.

In step 1650, the processor can create an artificial intelligence training dataset based on the answer associated with the binary set and the recording 330 of the first object 360, 370 at the first construction site 305.

The processor can train an artificial intelligence based on the artificial intelligence training dataset. The processor can provide to the artificial intelligence a second recording recorded at a second construction site and a prompt requesting a stage of construction associated with a second object included in the second recording, where the second object is represented by the node 1410, 1420 in the hierarchy 1400. The processor can obtain from the artificial intelligence an indication of the stage of construction associated with the second object, where the stage of construction corresponds to the multiple questions. For example, the multiple questions can include:
1. Has the construction of the object started?
2. Has the support for the object been installed?
3. Is the object in position?
4. Is the object bolted?
5. Is the object insulated?

The answer obtained from the artificial intelligence can be a vector such as [1, 1, 1, 0, 0], where 1 indicates the answer in the affirmative, and 0 indicates the answer in the negative. Based on the answer, the processor can determine the stage of the construction. For example, in the above case the third stage of the construction is completed, namely the object is in position, however the object has not been bolted and insulated.

The processor can obtain a second recording recorded at a second construction site. The processor can identify a second object in the second recording by performing the following steps. First, the processor can obtain multiple vectors representing multiple appearances of multiple virtual objects 365, 375 in a three-dimensional computer model 320 associated with the construction site 305, where a vector among the multiple vectors corresponds to a fourth object among the multiple objects. Second, the processor can obtain a third vector representing an appearance of a third object 360, 370 associated with a third recording 330. Third, the processor can determine whether the third vector matches the vector among the multiple vectors within a predetermined threshold, such as 0.6 or above. Fourth, upon determining that the third vector matches the vector among the multiple vectors, the processor can create a map between an indication of the third object 360, 370 associated with the third recording and an indication of the fourth virtual object 365, 375 among the multiple objects. Fifth, the processor can train an artificial intelligence using the map. Sixth, the processor can provide the second recording to the artificial intelligence, and a prompt requesting identifying the second object. Seventh, the processor can obtain from the artificial intelligence a recording of the second object in the second recording. In this way, the processor can identify objects in the recording, e.g., segment the recording, without using a three-dimensional computer model 320, and instead using artificial intelligence trained to segment the recording.

The processor can obtain a second recording 330 recorded at a second construction site 305. The processor can identify a second object 360, 370 in the second recording 330, using artificial intelligence or VSLAM techniques described in this application. The processor can determine a second node 1410, 1420 in the hierarchy 1400 representing the second object 360, 370. The processor can train an artificial intelligence based on the artificial intelligence training dataset. The processor can provide to the artificial intelligence a second recording 330 recorded at a second construction site 305, the second object 360, 370, the second node 1410, 1420, and a prompt requesting a stage of construction associated with a second object 360, 370 included in the second recording 330. The second object 360, 370 can be represented by the node 1410, 1420 in the hierarchy 1400. The processor can obtain from the artificial intelligence an indication of the stage of construction associated with the second object 360, 370, where the stage of construction corresponds to the multiple questions, as described in this application.

The processor can obtain a first three-dimensional computer model 320 of a first construction site 305 including a first multiplicity of virtual objects 365, 375, where a first virtual object 365, 375 among the first multiplicity of virtual objects represents a completed stage of construction associated with the first object at the first construction site 305. The processor can present the recording of the first object 360, 370, the first virtual object 365, 375 representing the completed stage of construction associated with the first object, and the multiple questions 1450 to a user. The processor can receive the answer associated with the binary set from the user.

The processor can obtain multiple questions 1450 associated with a node 1410, 1420 in the hierarchy 1400, where the multiple questions include an ordered sequence of questions indicating progressive stages of construction. An initial question among the multiple questions requests an indication of whether the project has started. A first subsequent question requests an indication of whether a support for the first object has been installed. A second subsequent question requests an indication of whether the first object is in position. A third subsequent question requests an indication of whether the first object is bolted. A fourth subsequent question requests an indication of whether the first object is insulated.

### Computer System

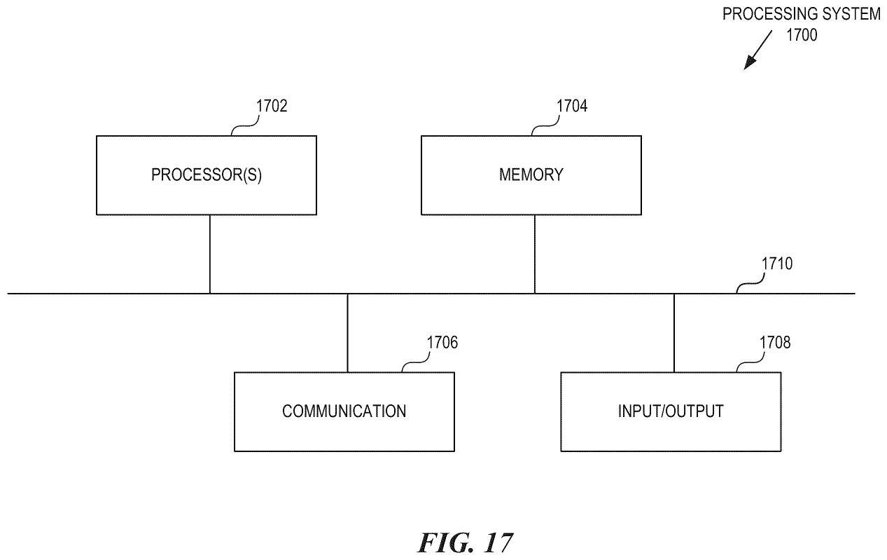

FIG. 17 is a block diagram illustrating an example of a processing system in which at least some operations described herein can be implemented. The processing system can be processing system 1700, which represents a system that can run any of the methods/algorithms described above. For example, the processing system 1700 can be computer system 135, or can be a processing device included in robot 110, LIDAR system 115, or imaging system 120, among others. A system may include two or more processing devices such as represented in FIG. 17, which may be coupled to each other via a network or multiple networks. A network can be referred to as a communication network.

In the illustrated embodiment, the processing system 1700 includes one or more processors 1702, memory 1704, a communication device 1706, and one or more input/output (I/O) devices 1708, all coupled to each other through an interconnect 1710. The interconnect 1710 may be or include one or more conductive traces, buses, point-to-point connections, controllers, adapters, and/or other conventional connection devices. Each of the processors 1702 may be or include, for example, one or more general-purpose programmable microprocessors or microprocessor cores, microcontrollers, application specific integrated circuits (ASICs), programmable gate arrays, or the like, or a combination of such devices. The processor(s) 1702 control the overall operation of the processing system 1700. The memory 1704 may be or include one or more physical storage devices, which may be in the form of random-access memory (RAM), read-only memory (ROM) (which may be erasable and programmable), flash memory, miniature hard disk drive, or other suitable type of storage device, or a combination of such devices. The memory 1704 may store data and instructions that configure the processor(s) 1702 to execute operations in accordance with the techniques described above. The communication device 1706 may be or include, for example, an Ethernet adapter, cable modem, Wi-Fi adapter, cellular transceiver, Bluetooth transceiver, or the like, or a combination thereof. Depending on the specific nature and purpose of the processing system 1700, the I/O devices 1708 can include devices such as a display (which may be a touch screen display), audio speaker, keyboard, mouse or other pointing device, microphone, camera, etc.

While processes or blocks are presented in a given order, alternative embodiments may perform routines having steps, or employ systems having blocks, in a different order, and some processes or blocks may be deleted, moved, added, subdivided, combined, and/or modified to provide alternative or sub-combinations, or may be replicated (e.g., performed multiple times). Each of these processes or blocks may be implemented in a variety of different ways. In addition, while processes or blocks are at times shown as being performed in series, these processes or blocks may instead be performed in parallel, or may be performed at different times. When a process or step is “based on” a value or a computation, the process or step should be interpreted as based at least on that value or that computation.

Software or firmware to implement the techniques introduced here may be stored on a machine-readable storage medium and may be executed by one or more general-purpose or special-purpose programmable microprocessors. A “machine-readable medium,” as the term is used herein, includes any mechanism that can store information in a form accessible by a machine (a machine may be, for example, a computer, network device, cellular phone, personal digital assistant (PDA), manufacturing tool, any device with one or more processors, etc.). For example, a machine-accessible medium includes recordable/non-recordable media (e.g., ROM, RAM, magnetic disk storage media, optical storage media, flash memory devices, etc.).

Note that any and all of the embodiments described above can be combined with each other, except to the extent that it may be stated otherwise above or to the extent that any such embodiments might be mutually exclusive in function and/or structure.

Although the present invention has been described with reference to specific exemplary embodiments, it will be recognized that the invention is not limited to the embodiments described but can be practiced with modification and alteration within the spirit and scope of the disclosed embodiments. Accordingly, the specification and drawings are to be regarded in an illustrative sense rather than a restrictive sense.

Physical and functional components (e.g., devices, engines, modules, and data repositories) associated with processing system 1700 can be implemented as circuitry, firmware, software, other executable instructions, or any combination thereof. For example, the functional components can be implemented in the form of special-purpose circuitry, one or more appropriately programmed processors, a single board chip, a field programmable gate array, a general-purpose computing device configured by executable instructions, a virtual machine configured by executable instructions, a cloud computing environment configured by executable instructions, or any combination thereof. For example, the functional components described can be implemented as instructions on a tangible storage memory capable of being executed by a processor or other integrated circuit chip. The tangible storage memory can be computer-readable data storage. The tangible storage memory may be volatile or non-volatile memory. In some embodiments, the volatile memory may be considered “non-transitory” in the sense that it is not a transitory signal. Memory space and storages described in the figures can be implemented with the tangible storage memory as well, including volatile or non-volatile memory.

Each of the functional components may operate individually and independently of other functional components. Some or all of the functional components may be executed on the same host device or on separate devices. The separate devices can be coupled through one or more communication channels (e.g., wireless or wired channel) to coordinate their operations. Some or all of the functional components may be combined as one component. A single functional component may be divided into sub-components, each sub-component performing a separate method step or method steps of the single component.

In some embodiments, at least some of the functional components share access to a memory space. For example, one functional component may access data accessed by or transformed by another functional component. The functional components may be considered “coupled” to one another if they share a physical connection or a virtual connection, directly or indirectly, allowing data accessed or modified by one functional component to be accessed in another functional component. In some embodiments, at least some of the functional components can be upgraded or modified remotely (e.g., by reconfiguring executable instructions that implement a portion of the functional components). Other arrays, systems, and devices described above may include additional, fewer, or different functional components for various applications.

Aspects of the disclosed embodiments may be described in terms of algorithms and symbolic representations of operations on data bits stored in memory. These algorithmic descriptions and symbolic representations generally include a sequence of operations leading to a desired result. The operations require physical manipulations of physical quantities. Usually, though not necessarily, these quantities take the form of electric or magnetic signals that are capable of being stored, transferred, combined, compared, and otherwise manipulated. Customarily, and for convenience, these signals are referred to as bits, values, elements, symbols, characters, terms, numbers, or the like. These and similar terms are associated with physical quantities and are merely convenient labels applied to these quantities.

While embodiments have been described in the context of fully functioning computers, those skilled in the art will appreciate that the various embodiments are capable of being distributed as a program product in a variety of forms and that the disclosure applies equally, regardless of the particular type of machine or computer-readable media used to actually effect the embodiments.

1. A non-transitory, computer-readable storage medium comprising instructions recorded thereon, wherein the instructions, when executed by at least one data processor of a system, cause the system to:
obtain a hierarchy representing a construction site,
wherein the hierarchy includes a parent node and a child node,
wherein the parent node indicates a function associated with an object at the construction site and the child node indicates an object type associated with the object at the construction site;
obtain a first three-dimensional computer model of a first construction site including a first multiplicity of virtual objects,
wherein a first virtual object among the first multiplicity of virtual objects corresponds to a first object at the first construction site;
based on the hierarchy representing the construction site, and the first three-dimensional computer model of the first construction site, create a first map between the hierarchy representing the construction site and the first three-dimensional computer model of the first construction site;
train an artificial intelligence based on the first map;
provide to the artificial intelligence a second three-dimensional computer model of a second construction site,
wherein the second three-dimensional computer model is different from the first three-dimensional computer model; and
receive from the artificial intelligence a second map between the hierarchy representing the construction site and the second three-dimensional computer model.

2. The non-transitory, computer-readable storage medium of claim 1, comprising instructions to:
obtain the first three-dimensional computer model of the first construction site including multiple virtual objects,
wherein the first three-dimensional computer model includes first metadata associated with the first virtual object;
determine a location of the first virtual object in the hierarchy representing the construction site; and
associate the first metadata with the location of the first virtual object in the hierarchy representing the construction site.

3. The non-transitory, computer-readable storage medium of claim 1, comprising instructions to:
obtain the first three-dimensional computer model of the first construction site including multiple virtual objects,
wherein the first three-dimensional computer model includes first metadata associated with the first virtual object;
determine a first location of the first virtual object in the hierarchy representing the construction site;
associate the first metadata with the first location of the first virtual object in the hierarchy representing the construction site;
obtain the second three-dimensional computer model of the second construction site,
wherein the second three-dimensional computer model includes a second multiplicity of virtual objects,
wherein a second virtual object among the second multiplicity of virtual objects does not include metadata;
based on the second map, obtain a second location of the second virtual object in the hierarchy representing the construction site; and
based on the second location, retrieve, from the hierarchy representing the construction site, metadata associated with the second location, thereby augmenting the second three-dimensional computer model with missing metadata.

4. The non-transitory, computer-readable storage medium of claim 1, comprising instructions to:
obtain the first three-dimensional computer model of the first construction site including multiple virtual objects,
wherein the first three-dimensional computer model includes first metadata associated with the first virtual object,
wherein the first metadata includes size associated with the first virtual object or type associated with the first virtual object;
determine a location of the first virtual object in the hierarchy representing the construction site; and
associate the first metadata with the location of the first virtual object in the hierarchy representing the construction site.

5. The non-transitory, computer-readable storage medium of claim 1, wherein the first three-dimensional computer model is represented as a first building information model, and the second three-dimensional computer model is represented as a second building information model.

6. The non-transitory, computer-readable storage medium of claim 1, comprising instructions to:
assign multiple questions associated to a node in the hierarchy representing the construction site,
wherein a question among the multiple questions requests an indication of a stage of construction associated with the object at the construction site represented by the node,
wherein the question among the multiple questions requests an answer from a binary set.

7. The non-transitory, computer-readable storage medium of claim 1, comprising instructions to:
obtain multiple questions associated with a node in the hierarchy representing the first construction site,
wherein a question among the multiple questions requests an indication of a stage of construction associated with the first object at the first construction site represented by the node,
wherein the question among the multiple questions requests an answer from a binary set;
obtain a recording of the first object at the first construction site;
present the multiple questions to a user;
receive the answer associated with the binary set from the user; and
create an artificial intelligence training dataset based on the answer associated with the binary set and the recording of the first object at the first construction site.

8. A method comprising:
obtaining a hierarchy representing a construction site,
wherein the hierarchy includes a parent node and a child node,
wherein the parent node indicates a function associated with an object at the construction site and the child node indicates an object type associated with the object at the construction site;
obtaining a first computer model of a first construction site including a first multiplicity of virtual objects,
wherein a first virtual object among the first multiplicity of virtual objects corresponds to a first object at the first construction site;
based on the hierarchy representing the construction site, and the first computer model of the first construction site, creating a first map between the hierarchy representing the construction site and the first computer model of the first construction site;
training an artificial intelligence based on the first map;
providing to the artificial intelligence a second computer model of a second construction site,
wherein the second computer model is different from the first computer model; and
receiving from the artificial intelligence a second map between the hierarchy representing the construction site and the second computer model.

9. The method of claim 8, comprising:
obtaining the first computer model of the first construction site including multiple virtual objects,
wherein the first computer model includes first metadata associated with the first virtual object;
determining a location of the first virtual object in the hierarchy representing the construction site; and
associating the first metadata with the location of the first virtual object in the hierarchy representing the construction site.

10. The method of claim 8, comprising:
obtaining the first computer model of the first construction site including multiple virtual objects,
wherein the first computer model includes first metadata associated with the first virtual object;
determining a first location of the first virtual object in the hierarchy representing the construction site;
associating the first metadata with the first location of the first virtual object in the hierarchy representing the construction site;
obtaining the second computer model of the second construction site,
wherein the second computer model includes a second multiplicity of virtual objects,
wherein a second virtual object among the second multiplicity of virtual objects does not include metadata;
based on the second map, obtaining a second location of the second virtual object in the hierarchy representing the construction site; and
based on the second location, retrieving, from the hierarchy representing the construction site, metadata associated with the second location, thereby augmenting the second computer model with missing metadata.

11. The method of claim 8, comprising:
obtaining the first computer model of the first construction site including multiple virtual objects,
wherein the first computer model includes first metadata associated with the first virtual object,
wherein the first metadata includes size associated with the first virtual object or type associated with the first virtual object;
determining a location of the first virtual object in the hierarchy representing the construction site; and
associating the first metadata with the location of the first virtual object in the hierarchy representing the construction site.

12. The method of claim 8, comprising:
assigning multiple questions associated to a node in the hierarchy representing the construction site,
wherein a question among the multiple questions requests an indication of a stage of construction associated with the object at the construction site represented by the node,
wherein the question among the multiple questions requests an answer from a binary set.

13. The method of claim 8, comprising:
obtaining multiple questions associated with a node in the hierarchy representing the first construction site,
wherein a question among the multiple questions requests an indication of a stage of construction associated with the first object at the first construction site represented by the node,
wherein the question among the multiple questions requests an answer from a binary set;
obtaining a recording of the first object at the first construction site;
presenting the multiple questions to a user;
receiving the answer associated with the binary set from the user; and
creating an artificial intelligence training dataset based on the answer associated with the binary set and the recording of the first object at the first construction site.

14. A system comprising:
at least one hardware processor; and
at least one non-transitory memory storing instructions, which, when executed by the at least one hardware processor, cause the system to:
obtain a hierarchy representing a construction site,
wherein the hierarchy includes a parent node and a child node,
wherein the parent node indicates a function associated with an object at the construction site and the child node indicates an object type associated with the object at the construction site;
obtain a first computer model of a first construction site including a first multiplicity of virtual objects,
wherein a first virtual object among the first multiplicity of virtual objects corresponds to a first object at the first construction site;
based on the hierarchy representing the construction site, and the first computer model of the first construction site, create a first map between the hierarchy representing the construction site and the first computer model of the first construction site;
train an artificial intelligence based on the first map;
provide to the artificial intelligence a second computer model of a second construction site,
wherein the second computer model is different from the first computer model; and
receive from the artificial intelligence a second map between the hierarchy representing the construction site and the second computer model.

15. The system of claim 14, comprising instructions to:
obtain the first computer model of the first construction site including multiple virtual objects,
wherein the first computer model includes first metadata associated with the first virtual object;
determine a location of the first virtual object in the hierarchy representing the construction site; and
associate the first metadata with the location of the first virtual object in the hierarchy representing the construction site.

16. The system of claim 14, comprising instructions to:
obtain the first computer model of the first construction site including multiple virtual objects,
wherein the first computer model includes first metadata associated with the first virtual object;
determine a first location of the first virtual object in the hierarchy representing the construction site;
associate the first metadata with the first location of the first virtual object in the hierarchy representing the construction site;
obtain the second computer model of the second construction site,
wherein the second computer model includes a second multiplicity of virtual objects,
wherein a second virtual object among the second multiplicity of virtual objects does not include metadata;
based on the second map, obtain a second location of the second virtual object in the hierarchy representing the construction site; and
based on the second location, retrieve, from the hierarchy representing the construction site, metadata associated with the second location, thereby augmenting the second computer model with missing metadata.

17. The system of claim 14, comprising instructions to:
obtain a first computer model of the first construction site including multiple virtual objects,
wherein the first computer model includes first metadata associated with the first virtual object,
wherein the first metadata includes size associated with the first virtual object or type associated with the first virtual object;
determine a location of the first virtual object in the hierarchy representing the construction site; and
associate the first metadata with the location of the first virtual object in the hierarchy representing the construction site.

18. The system of claim 14, wherein the first computer model is represented as a first building information model, and the second computer model is represented as a second building information model.

19. The system of claim 14, comprising instructions to:
assign multiple questions associated with a node in the hierarchy representing the construction site,
wherein a question among the multiple questions requests an indication of a stage of construction associated with the object at the construction site represented by the node,
wherein the question among the multiple questions requests an answer from a binary set.

20. The system of claim 14, comprising instructions to:
obtain multiple questions associated with a node in the hierarchy representing the first construction site,
wherein a question among the multiple questions requests an indication of a stage of construction associated with the first object at the first construction site represented by the node,
wherein the question among the multiple questions requests an answer from a binary set;
obtain a recording of the first object at the first construction site;
present the multiple questions to a user;
receive the answer associated with the binary set from the user; and
create an artificial intelligence training dataset based on the answer associated with the binary set and the recording of the first object at the first construction site.
